(19) United States
(12) Patent Application Publication
(10) Pub. No.: US 2023/0253536 A1
(43) Pub. Date: Aug. 10, 2023

(54) DISPLAY DEVICE

(71) Applicant: Samsung Display Co., LTD., Yongin-si (KR)

(72) Inventors: Bon Yong KOO, Hwaseong-si (KR); Sun Hwa LEE, Yongin-si (KR); Su Jin LEE, Hwaseong-si (KR); Jae Yong JANG, Seoul (KR)

(73) Assignee: Samsung Display Co., LTD., Yongin-si (KR)

(21) Appl. No.: 17/978,323

(22) Filed: Nov. 1, 2022

(30) Foreign Application Priority Data
Feb. 8, 2022 (KR) 10-2022-0016005

(51) Int. Cl. H01L 33/62; H01L 33/42; H01L 27/15

(52) U.S. Cl. CPC H01L 33/62; H01L 33/42; H01L 27/156

(57) ABSTRACT

A display device includes a substrate, an insulating film disposed on the substrate, a first sub-power supply line disposed on the insulating film and applied by a first power supply voltage, a first organic film disposed on the first sub-power supply line, a second sub-power supply line disposed on the first organic film and electrically connected to the first sub-power supply line through a first power supply hole formed in the first organic film, a third sub-power supply line disposed on the second sub-power supply line, a pixel electrode disposed on the first organic film, a light-emitting element disposed on the pixel electrode, a planarization film disposed on sides of the light-emitting element, and a common electrode disposed on the light-emitting element and the planarization film. The planarization film is disposed on the third sub-power supply line.

### CROSS-REFERENCE TO RELATED APPLICATION(S)

This application claims priority to and benefits of Korean Patent Application No. 10-2022-0016005 under 35 U.S.C. § 119, filed on Feb. 8, 2022, in the Korean Intellectual Property Office, the entire contents of which are incorporated hereby by reference.

### BACKGROUND

### 1. Technical Field

Embodiments of the invention relate to a display device.

### 2. Description of the Related Art

As the information society has been developed, the demand for display devices for displaying images has been diversified. Here, the display devices may be flat panel display devices such as a liquid crystal display (LCD) device, a field emission display (FED) device, or a light-emitting display device, and the light-emitting display device may be implemented as one of an organic light-emitting display device including organic light-emitting diodes (OLEDs), an inorganic light-emitting display device including inorganic semiconductor elements, and a micro-light-emitting diode (microLED) display device including microLEDs. In the microLED display device, the microLEDs are bonded to pixel electrodes, and thus, the resistance of the pixel electrodes is required to be lowered.

The above information disclosed in this Background section is only for understanding of the background of the invention, and, therefore, it may contain information that does not constitute prior art.

### SUMMARY

Embodiments provide a display device capable of lowering the resistance of pixel electrodes that are connected to micro-light-emitting diodes (microLEDs).

Additional features of the invention will be set forth in the description which follows, and in part will be apparent from the description, or may be learned by practice of the invention.

In an embodiment, a display device may include a substrate, an insulating film disposed on the substrate, a first sub-power supply line disposed on the insulating film and applied by a first power supply voltage, a first organic film disposed on the first sub-power supply line, a second sub-power supply line disposed on the first organic film and electrically connected to the first sub-power supply line through a first power supply hole formed in the first organic film, a third sub-power supply line disposed on the second sub-power supply line, a pixel electrode disposed on the first organic film, a light-emitting element disposed on the pixel electrode, a planarization film disposed on sides of the light-emitting element, and a common electrode disposed on the light-emitting element and the planarization film. The planarization film may be disposed on the third sub-power supply line.

The pixel electrode and the third sub-power supply line may include a same material.

The pixel electrode and the third sub-power supply line may include a material different from a material of the first sub-power supply line and from a material of the second sub-power supply line.

The pixel electrode and the third sub-power supply line may include copper (Cu). Each of the first and second sub-power supply lines may include a first layer formed of titanium (Ti), a second layer formed of aluminum (Al), and a third layer formed of Ti.

An upper surface of the second sub-power supply line may be in contact with a lower surface of the third sub-power supply line.

The display device may further include a fourth sub-power supply line disposed on the insulating film and applied by a second power supply voltage, a fifth sub-power supply line disposed on the first organic film and electrically connected to the fourth sub-power supply line through a second power supply hole formed in the first organic film, and a sixth sub-power supply line disposed on the fifth sub-power supply line.

The first power supply voltage may be supplied to the common electrode.

The planarization film may be disposed on the sixth sub-power supply line.

The pixel electrode and the sixth sub-power supply line may include a same material.

The sixth sub-power supply line may include a material different from a material of the fourth sub-power supply line and from a material of the fifth sub-power supply line.

The third and sixth sub-power supply lines may include a same material.

The first sub-power supply line and the fourth sub-power supply line may include a same material. The second sub-power supply line and the fifth sub-power supply line may include a same material.

An upper surface of the fifth sub-power supply line may be in contact with a lower surface of the sixth sub-power supply line.

In an embodiment, a display device may include a substrate, a scan line disposed on the substrate, a first insulating film disposed on the scan line, a first sub-clock line disposed on the first insulating film and applied by a clock signal, a first organic film disposed on the first sub-clock line, a second sub-clock line disposed on the first organic film and electrically connected to the first sub-clock line through a first contact hole formed in the first organic film, a third sub-clock line disposed on the second sub-clock line, a pixel electrode disposed on the first organic film, a light-emitting element disposed on the pixel electrode, a planarization film disposed on sides of the light-emitting element, and a common electrode disposed on the light-emitting element and the planarization film. The planarization film is disposed on the third sub-clock line.

The display device may further include a scan driver that applies a scan signal to the scan line in accordance with the clock signal.

The pixel electrode and the third sub-clock line may include a same material.

The pixel electrode and the third sub-clock line may include a material different from a material of the first sub-clock line and from a material of the second sub-clock line.

In an embodiment, a display device may include a substrate, an insulating film disposed on the substrate, a pad disposed on the insulating film, a first organic film disposed on the pad, a pad-shielding electrode disposed on the first organic film and electrically connected to the pad through a pad hole formed in the first organic film, a pixel electrode disposed on the first organic film, a light-emitting element disposed on the pixel electrode, a planarization film disposed on sides of the light-emitting element, and a common electrode disposed on the light-emitting element and the planarization film.

The display device may further include a first sub-power supply line disposed on the insulating film and applied by a first power supply voltage, a second sub-power supply line disposed on the first organic film and electrically connected to the first sub-power supply line through a first power supply hole formed in the first organic film, and a third sub-power supply line disposed on the second sub-power supply line. The first sub-power supply line and the pad may include a same material.

The pad-shielding electrode may include a transparent conductive oxide (TCO).

According to the aforementioned and other embodiments, as pixel electrodes are bonded to first, second, and third light-emitting elements, the pixel electrodes may be formed of a metal with a low surface resistance, such as Cu. As a result, the contact resistance between the pixel electrodes and the first, second, and third light-emitting elements may be reduced.

Also, as a first power supply line includes first, second, and third sub-power supply lines, which are disposed in three different layers, the area of the first power supply line may be increased. Also, as the third sub-power supply line is formed of a metal with a low surface resistance, such as Cu, the resistance of the first power supply line may be lowered. Thus, the width of the first power supply line in a non-display area may be reduced, and the width of the non-display area may be reduced. Also, ripples (or coupling noise) that may be caused by voltage variations between the first power supply line and other lines overlapping the first power supply line may be minimized.

Also, as a clock connecting line includes first, second, and third sub-clock lines, which are disposed in multiple layers, the area of the clock connecting line may be increased. Also, the third sub-clock line is formed of a metal with a low surface resistance, such as Cu, the resistance of a scan clock line may be lowered. Accordingly, the load of a scan signal output to a scan line, e.g., an RC delay, may be reduced.

It is to be understood that both the foregoing general description and the following detailed description are illustrative and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the invention.

FIG. 1 is a schematic perspective view of a display device according to an embodiment.

FIGS. 2 and 3 are schematic plan views of the display device of FIG. 1.

FIG. 4 is a schematic diagram of an equivalent circuit of a subpixel of a display panel of the display device of FIG. 1.

FIG. 5 is a schematic diagram of another example of the equivalent circuit of the subpixel of the display panel of the display device of FIG. 1.

FIG. 6 is a schematic layout view illustrating subpixels in a display area of the display panel of the display device of FIG. 1.

FIG. 7 is a schematic cross-sectional view taken along line A-A′ of FIG. 6.

FIG. 8 is a schematic cross-sectional view of part B of FIG. 7.

FIG. 9 is a schematic layout view of an area A of FIG. 2.

FIG. 10 is a schematic layout view of an area C of FIG. 9

FIG. 11 is a schematic cross-sectional view taken along line B-B′ of FIG. 10.

FIG. 12 is a schematic cross-sectional view taken along line C-C′ of FIG. 10

FIG. 13 is a schematic cross-sectional view of a pad of the display panel of FIG. 8.

FIG. 14 is a schematic layout view of part B of a display panel of a display device according to an embodiment.

FIG. 15 is a schematic cross-sectional view taken along line H-H′ of FIG. 14.

FIG. 16 is a schematic cross-sectional view taken along line I-I′ of FIG. 14.

FIG. 17 is a layout view of a first scan driver in a non-display area of the display panel of the display device of FIG. 1.

FIG. 18 is a schematic cross-sectional view taken along line J-J′ of FIG. 17.

FIG. 19 is a schematic layout view of another example of the first scan driver in the non-display area of the display panel of the display device of FIG. 1.

FIG. 20 is a schematic cross-sectional view taken along line K-K′ of FIG. 17.

FIG. 21 is a schematic perspective view of a smart device including a display device according to the embodiment of FIG. 1.

FIG. 22 is a schematic perspective view of a virtual reality (VR) device including a display device according to the embodiment of FIG. 1.

FIG. 23 is a schematic perspective view of a dashboard and a center console of an automobile including display devices according to the embodiment of FIG. 1.

FIG. 24 is a transparent display device including a display device according to the embodiment of FIG. 1.

FIG. 25 is a schematic perspective view of a display device according to an embodiment.

FIG. 26 is a schematic perspective view of a smart device including a display device according to the embodiment of FIG. 25.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the invention disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another example without departing from the invention.

Unless otherwise specified, the illustrated embodiments are to be understood as providing illustrative features of varying detail of some ways in which the invention may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any requirement for specific materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. In case that an embodiment may be implemented differently, a specific process order may be performed differently from the described order. For example, two consecutively described processes may be performed substantially at the same time or performed in an order opposite to the described order. Also, like reference numerals denote like elements.

In case that an element, such as a layer, is referred to as being “on,” “connected to,” or “coupled to” another element or layer, it may be directly on, connected to, or coupled to the other element or layer or intervening elements or layers may be present. In case that, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the illustrative term “below” can encompass both an orientation of above and below. Furthermore, the apparatus may be otherwise oriented (e.g., rotated 90 degrees or at other orientations), and, as such, the spatially relative descriptors used herein interpreted accordingly. As used herein “in a plan view” means as viewed from a position normal to a plane of a substrate.

The terminology used herein is for the purpose of describing embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” in case that used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

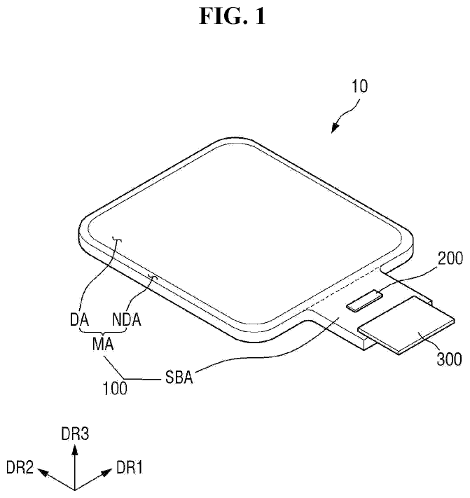

FIG. 1 is a schematic perspective view of a display device according to an embodiment.

Referring to FIG. 1, a display device 10, which is a device displaying a moving or still image, may be used not only in a portable electronic device such as a mobile phone, a smartphone, a tablet personal computer (PC), a smart watch, a watchphone, a mobile communication terminal, an electronic notepad, an electronic book, a portable multimedia player (PMP), a navigation device, or an ultramobile PC (UMPC), but also in various other products such as a television (TV), a notebook computer, a monitor, a billboard, or an Internet-of-Things (IoT) device.

The display device 10 may be an organic light-emitting display device including organic light-emitting diodes (OLEDs), a quantum-dot light-emitting display device including a quantum-dot light-emitting layer, an inorganic light-emitting display device including an inorganic semiconductor, or an ultrasmall light-emitting diode (LED) display device including ultrasmall LEDs such as microLEDs or nanoLEDs. The display device 10 will hereinafter be described as being an ultrasmall light-emitting display device, but embodiments are not limited thereto. For convenience, ultrasmall LEDs will hereinafter be referred to as microLEDs.

The display device 10 may include a display panel 100, a display driving circuit 200, and a circuit board 300.

The display panel 100 may be formed in a rectangular shape having short sides extending in a first direction DR1 and long sides extending in a second direction DR2 in a plan view. The corners where the long sides and the short sides of the display panel 100 meet may be rounded to have a curvature (e.g., a predetermined curvature) or may be right-angled. The planar shape of the display panel 100 is not limited thereto, and the display panel 100 may be formed in various other shapes such as another polygonal shape, a circular shape, or an elliptical shape. The display panel 100 may be formed to be flat, but embodiments are not limited thereto. In one example, the display panel 100 may include curved parts that are disposed at both ends (e.g., opposite ends) of the display panel 100 and have a uniform or varying curvature. The display panel 100 may be formed to be flexible such as foldable, bendable, or rollable.

A substrate SUB of the display panel 100 may include a main area MA and a subarea SBA.

The main area MA may include a display area DA, which displays an image, and a non-display area NDA, which is around the display area DA. The display area DA may include subpixels SPX1, SPX2, and SPX3, which display an image. For example, the display area DA may include first subpixels SPX1, which emit first light, second subpixels SPX2, which emit second light, and third subpixels SPX3, which emit third light.

The subarea SBA may protrude from a side of the main area MA in the second direction DR2. FIG. 1 illustrates that the display panel 100 is unfolded, but the display panel 100 may be bendable. In case that the display panel 100 is bent, the subarea SBA may be disposed at the bottom portion of the display panel 100 and may overlap the main area MA in the thickness direction of the display panel 100, e.g., in a third direction DR3. A display driving circuit 200 may be disposed in the subarea SBA.

The display driving circuit 200 may generate signals and voltages for driving the display panel 100. The display driving circuit 200 may be formed as an integrated circuit (IC) and may be attached to the display panel 100 in a chip-on-glass (COG) or chip-on-glass (COG) manner or by ultrasonic bonding, but embodiments are not limited thereto. In another example, the display driving circuit 200 may be attached to a circuit board 300 in a chip-on-film (COF) manner.

The circuit board 300 may be attached to an end portion of the subarea SBA of the display panel 100. As a result, the circuit board 300 may be connected (e.g., electrically connected) to the display panel 100 and the display driving circuit 200. The display panel 100 and the display driving circuit 200 may receive digital video data, timing signals, and driving voltages through the circuit board 300. The circuit board 300 may be a printed circuit board (PCB), a flexible PCB (FPCB), or a flexible film such as a COF.

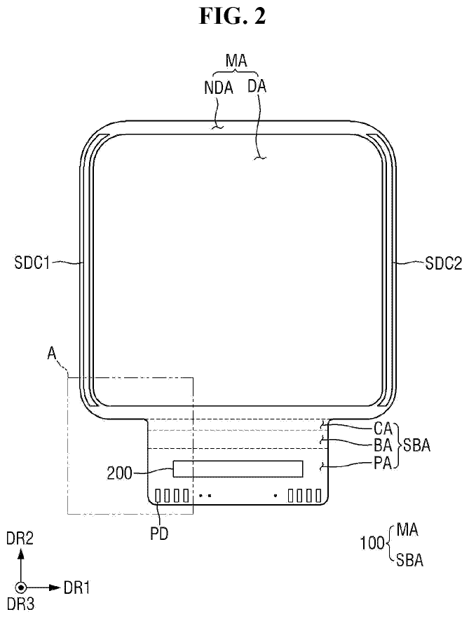

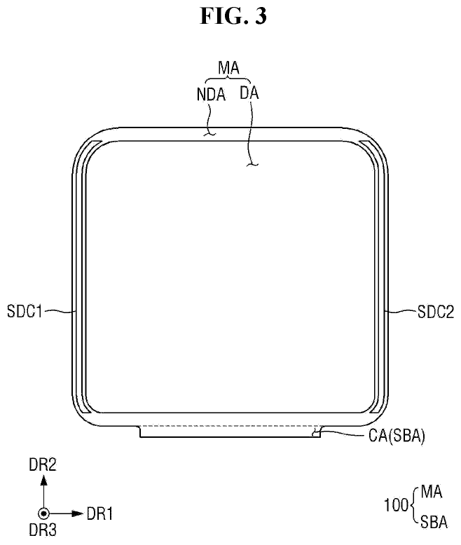

FIGS. 2 and 3 are schematic plan views of the display device of FIG. 1. FIG. 2 illustrates the display device 10 in an unfolded state, and FIG. 3 illustrates the display device 10 in a folded state.

Referring to FIGS. 2 and 3, the display panel 100 may include the main area MA and the subarea SBA.

The main area MA may include the display area DA, which displays an image, and the non-display area NDA, which is around the display area DA. The display area DA may account for most of the main area MA. The display area DA may be disposed in the middle area of the main area MA.

The non-display area NDA may be disposed adjacent to the display area DA. The non-display area NDA may be an area outside the display area DA. The non-display area NDA may be disposed to surround the display area DA. The non-display area NDA may be an edge area of the display panel 100.

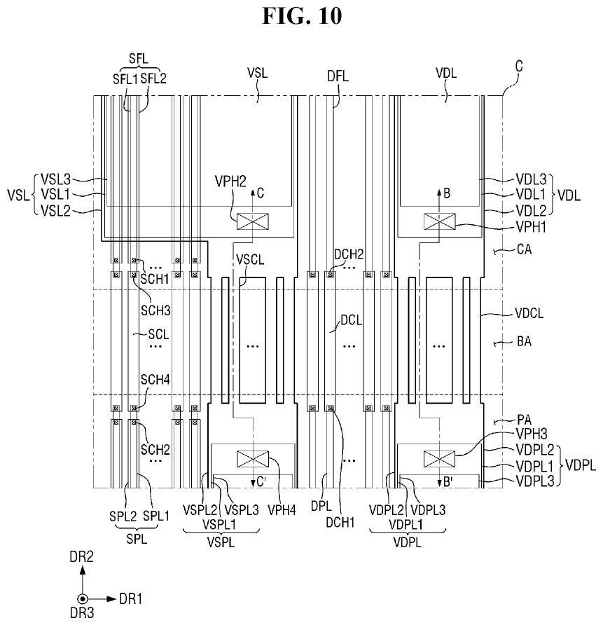

First and second scan drivers SDC1 and SDC2 may be disposed in the non-display area NDA. The first scan driver SDC1 may be disposed on a side of the display panel 100 (e.g., on the left side of the display panel 100), but embodiments are not limited thereto. The second scan driver SDC2 may be disposed on the other side of the display panel 100 (e.g., on the right side of the display panel 100), but embodiments are not limited thereto. The first and second scan drivers SDC1 and SDC2 may be connected (e.g., electrically connected) to the display driving circuit 200 through scan fan-out lines (e.g., “SFL” of FIG. 10). The first and second scan drivers SDC1 and SDC2 may receive scan control signals from the display driving circuit 200 and may generate scan signals and output the scan signals to scan lines in accordance with the scan control signals.

The subarea SBA may protrude from a side of the main area MA in the second direction DR2. The length, in the second direction DR2, of the subarea SBA may be less than the length, in the second direction DR2, of the main area MA. The length, in the first direction DR1, of the subarea SBA may be less than, or the same as, the length, in the first direction DR1, of the main area MA. The display panel 100 may be bendable, and thus, the subarea SBA may be disposed below the main area MA. For example, the subarea SBA may overlap the main area MA in the third direction DR3.

The subarea SBA may include a connecting area CA, a pad area PA, and a bending area BA.

The connecting area CA may be an area protruding from a side of the main area MA in the second direction DR2. A side of the connecting area CA may adjoin the non-display area NDA of the main area MA, and the other side of the connecting area CA may adjoin the bending area BA.

The pad area PA may be an area where pads PD and the display driving circuit 200 are disposed. The display driving circuit 200 may be attached to driving pads in the pad area PA via conductive adhesive members such as anisotropic conductive films (ACFs). The circuit board 300 may be attached to pads PD in the pad area PA via conductive adhesive members such as ACFs. A side of the pad area PA may adjoin the bending area BA.

The bending area BA may be an area where the display panel 100 is bent. In case that the display panel 100 is bent, the pad area PA may be disposed below the connecting area CA and the main area MA. The bending area BA may be disposed between the connecting area CA and the pad area PA. A side of the bending area BA may adjoin the connecting area CA, and the other side of the bending area BA may adjoin the pad area PA.

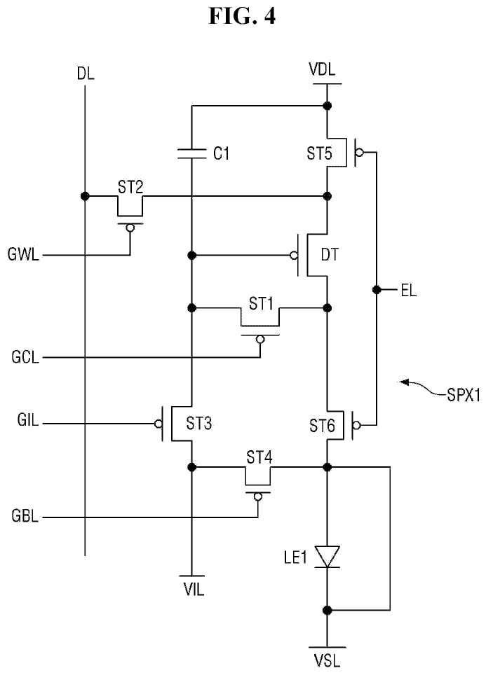

FIG. 4 is a schematic diagram of an equivalent circuit of a subpixel of the display panel of the display device of FIG. 1.

Referring to FIG. 4, a first subpixel SPX1 may be connected to scan lines (GWL, GIL, GCL, and GBL), an emission line EL, and a data line DL. For example, the first subpixel SPX1 may be connected to a write scan line GWL, an initialization scan line GIL, a control scan line GCL, a bias scan line GBL, the emission line EL, and the data line DL.

The first subpixel SPX1 may include a driving transistor DT, switching elements, a capacitor C1, and a first light-emitting element LE1. The switching elements may include first, second, third, fourth, fifth, and sixth transistors ST1, ST2, ST3, ST4, ST5, and ST6.

The driving transistor DT may include a gate electrode, a first electrode, and a second electrode. The driving transistor DT may control a drain-source current Ids (or a driving current) flowing between the first and second electrodes in accordance with a data voltage applied to the gate electrode.

The first light-emitting element LE1 may be an OLED including an anode (or a pixel electrode), a cathode (or a common electrode), and an organic light-emitting layer disposed between the anode and the cathode. In another example, the first light-emitting element LE1 may be an inorganic light-emitting element including an anode, a cathode, and an inorganic semiconductor disposed between the anode and the cathode. In another example, the first light-emitting element LE1 may be a quantum-dot light-emitting element including an anode, a cathode, and a quantum-dot light-emitting layer disposed between the anode and the cathode. In another example, the first light-emitting element LE1 may be a microLED. The first light-emitting element LE1 will hereinafter be described as being a microLED.

The first light-emitting element LE1 may emit light in accordance with the driving current Ids. The amount of light emitted by the first light-emitting element LE1 may be proportional to the driving current Ids. The anode of the first light-emitting element LE1 may be connected to a first electrode of the fourth transistor ST4 and a second electrode of the sixth transistor ST6, and the cathode of the first light-emitting element LE1 may be connected to a second power supply line VSL, to which a second power supply voltage is applied.

The capacitor C1 may be disposed between the second electrode of the driving transistor DT and a first power supply line VDL, to which a first power supply voltage is applied. The first power supply voltage may be higher than the second power supply voltage. A first electrode of the capacitor C1 may be connected to a second electrode of the driving transistor DT, and a second electrode of the capacitor C1 may be connected to the first power supply line VDL.

The first, second, third, fourth, fifth, and sixth transistors ST1, ST2, ST3, ST4, ST5, and ST6 and the driving transistor DT may all be formed as p-type metal-oxide semiconductor field-effect transistors (MOSFETs). For example, the active layers of the first, second, third, fourth, fifth, and sixth transistors ST1, ST2, ST3, ST4, ST5, and ST6 and the driving transistor DT may be formed of polysilicon or an oxide semiconductor.

A gate electrode of the second transistor ST2 may be connected to the write scan line GWL, and the gate electrode of the first transistor ST1 may be connected to the control scan line GCL. A gate electrode of the third transistor ST3 may be connected to the initialization scan line GLI, and a gate electrode of the fourth transistor ST4 may be connected to the bias scan line GBL. As the first, second, third, fourth, fifth, and sixth transistors ST1, ST2, ST3, ST4, ST5, and ST6 are formed as p-type MOSFETs, the first, second, third, fourth, fifth, and sixth transistors ST1, ST2, ST3, ST4, ST5, and ST6 may be turned on in case that scan signals having a gate-low voltage and an emission signal are applied to the control scan line GCL, the initialization scan line GIL, the write scan line GWL, and the bias scan line GBL, and the emission line EL. A first electrode of the third transistor ST3 and a first electrode of the fourth transistor ST5 may be connected to the initialization voltage line VIL.

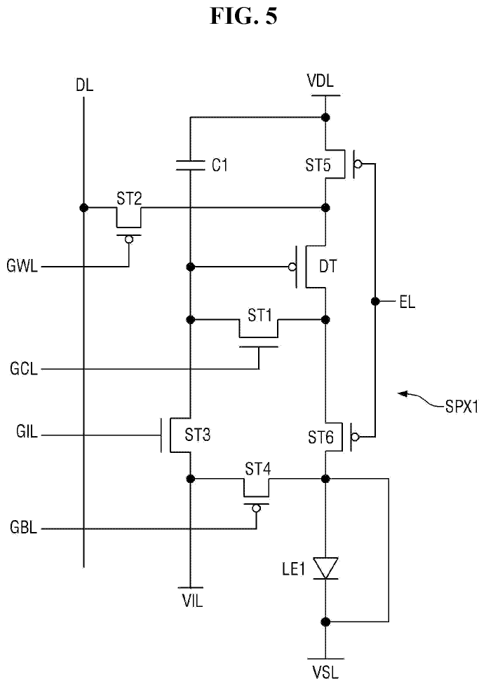

FIG. 5 is a schematic diagram of another example of the equivalent circuit of the subpixel of the display panel of the display device of FIG. 1.

Referring to FIG. 5, a driving transistor DT and second, fourth, fifth, and sixth transistors ST2, ST4, ST5, and ST6 may be formed as p-type MOSFETs, and first and third transistors ST1 and ST4 may be formed as n-type MOSFETs. The active layers of the driving transistor DT and the second, fourth, fifth, and sixth transistors ST2, ST4, ST5, and ST6, which are formed as p-type MOSFETs, may be formed of polysilicon, and the active layers of the first and third transistors ST1 and ST3, which are formed as n-type MOSFETs, may be formed of an oxide semiconductor. For example, the driving transistor DT and the second, fourth, fifth, and sixth transistors ST2, ST4, ST5, and ST6 may be disposed in a different layer from a layer in which the first and third transistors ST1 and ST3 are disposed.

As the first and third transistors ST1 and ST3 are formed as n-type MOSFETs, the first transistor ST 1 may be turned on in response to a control scan signal having a gate-high voltage, which is applied to a control scan line GCL, and the third transistor ST3 may be turned on in case that an initialization scan signal is applied to the initialization scan line GIL. For example, as the second, fourth, fifth, and sixth transistors ST2, ST4, ST5, and ST6 are formed as p-type MOSFETs, the second, fourth, fifth, and sixth transistors ST2, ST4, ST5, and ST6 may be turned on in case that scan signals having a gate-low voltage and an emission signal are applied to the write scan line GWL, the bias scan line GBL, and the emission line EL.

In another example, the fourth transistor ST4 may be formed as an n-type MOSFET. For example, the active layer of the fourth transistor ST4 may be formed of an oxide semiconductor, and the fourth transistor ST4 may be turned on in case that a bias scan signal having a gate-high voltage is applied to the bias scan line GBL.

In another example, the first, second, third, fourth, fifth, and sixth transistors ST1, ST2, ST3, ST4, ST5, and ST6 and the driving transistor DT may all be formed as n-type MOSFETs.

Schematic circuit diagrams of second and third subpixels SPX2 and SPX3 may be substantially the same as the schematic circuit diagram of FIG. 4 or 5 of the first subpixel SPX1, and thus, redundant descriptions thereof will be omitted for descriptive convenience.

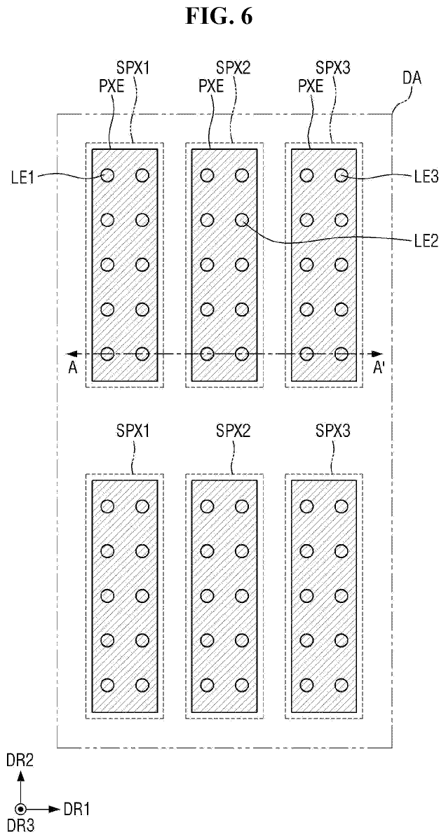

FIG. 6 is a schematic layout view illustrating subpixels in the display area of the display panel of the display device of FIG. 1.

Referring to FIG. 6, the display area DA may include subpixels. The subpixels may include first subpixels SPX1, second subpixels SPX2, and third subpixels SPX3.

Each of the first subpixels SPX1 may include a pixel electrode PXE and first light-emitting elements LE1, which emit first light. The first light may be light of a red wavelength range. The red wavelength range may be about 600 nm to about 750 nm, but embodiments are not limited thereto.

Each of the second subpixels SPX2 may include a pixel electrode PXE and second light-emitting elements LE2, which emit second light. The second light may be light of a green wavelength range. The green wavelength range may be about 480 nm to about 560 nm, but embodiments are not limited thereto.

Each of the third subpixels SPX3 may include a pixel electrode PXE and third light-emitting elements LE3, which emit third light. The third light may be light of a blue wavelength range. The blue wavelength range may be about 370 nm to about 460 nm, but embodiments are not limited thereto.

The first subpixels SPX1, the second subpixels SPX2, and the third subpixels SPX3 may be arranged along the first direction DR1. The first subpixels SPX1 may be arranged along the second direction DR2, the second subpixels SPX2 may be arranged along the second direction DR2, and the third subpixels SPX3 may be arranged along the second direction DR2.

Pixel electrodes PXE may have a rectangular shape in a plan view, but embodiments are not limited thereto.

First light-emitting elements LE1 may be arranged in the first and second directions DR1 and DR2, on the pixel electrode PXE of each of the first subpixels SPX1. For example, first light-emitting elements LE1 may be arranged in a matrix including five rows and two columns, on the pixel electrode PXE of each of the first subpixels SPX1. For example, ten first light-emitting elements LE1 may be disposed on the pixel electrode PXE of each of the first subpixels SPX1.

Second light-emitting elements LE2 may be arranged in the first and second directions DR1 and DR2, on the pixel electrode PXE of each of the second subpixels SPX2. For example, second light-emitting elements LE2 may be arranged in a matrix including five rows and two columns, on the pixel electrode PXE of each of the second subpixels SPX2. For example, ten second light-emitting elements LE2 may be disposed on the pixel electrode PXE of each of the second subpixels SPX2.

Third light-emitting elements LE3 may be arranged in the first and second directions DR1 and DR2, on the pixel electrode PXE of each of the third subpixels SPX3. For example, third light-emitting elements LE3 may be arranged in a matrix including five rows and two columns, on the pixel electrode PXE of each of the third subpixels SPX3. For example, ten third light-emitting elements LE3 may be disposed on the pixel electrode PXE of each of the third subpixels SPX3.

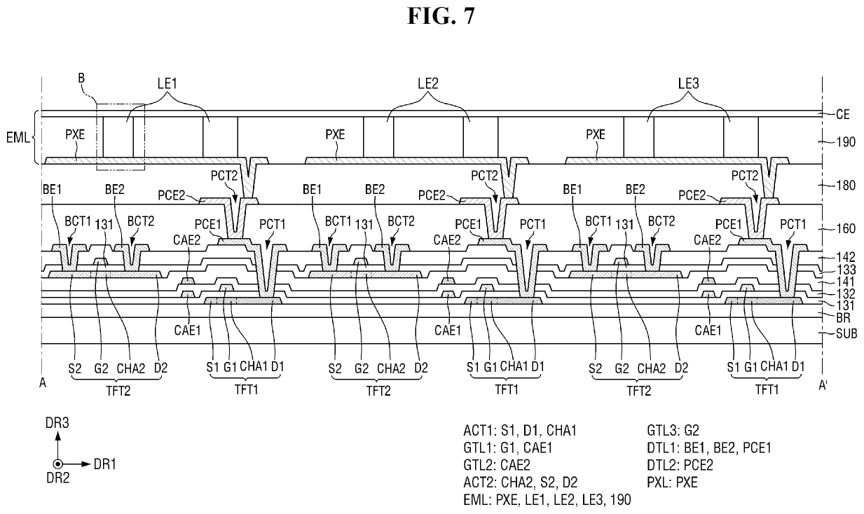

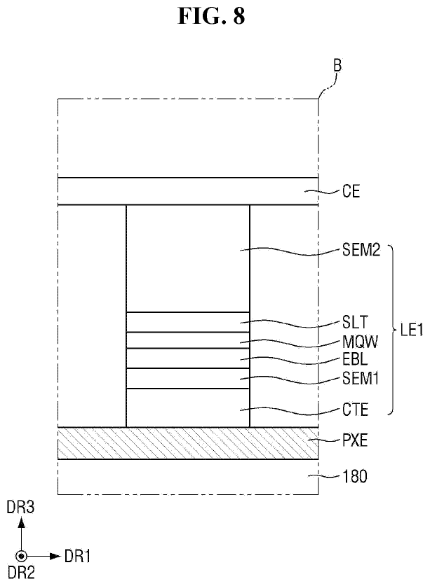

FIG. 7 is a schematic cross-sectional view taken along line A-A′ of FIG. 6. FIG. 8 is a schematic cross-sectional view of part B of FIG. 7. FIG. 8 illustrates a pixel electrode, a light-emitting element, a common electrode, and a third planarization.

Referring to FIGS. 7 and 8, a barrier film BR may be disposed on the substrate SUB. The substrate SUB may be formed of an insulating material such as a polymer resin. For example, the substrate SUB may be formed of polyimide. The substrate SUB may be a flexible substrate that is bendable, foldable, or rollable.

The barrier film BR may be a film for protecting transistors of a thin-film transistor (TFT) layer TFTL and light-emitting elements LE1, LE2, and LE3 of a light-emitting element layer EML. The barrier film BR may be formed of inorganic films that are alternately stacked each other. For example, the barrier film BR may be formed as a multilayer film in which at least one of a silicon nitride layer, a silicon oxynitride layer, a silicon oxide layer, a titanium oxide layer, and an aluminum oxide layer is alternately stacked each other.

First TFTs “TFT1” may be disposed on the barrier film BR. The first TFTs “TFT1” may correspond to one of the fourth and sixth transistors ST4 and ST6 of FIG. 5. Each of the first TFTs “TFT1” may include a first active layer ACT1 and a first gate electrode G1.

The first active layers ACT1 of the first TFTs “TFT1” may be disposed on the barrier film BR. The first active layers ACT1 of the first TFTs “TFT1” may include polycrystalline silicon, monocrystalline silicon, low-temperature polycrystalline silicon, or amorphous silicon.

Each of the first active layers ACT1 may include a first channel region CHA1, a first source region S1, and a first drain region D1. The first channel regions CHA1 of the first active layers ACT1 may be areas that overlaps the first gate electrodes G1 of the first TFTs “TFT1” in the thickness direction of the substrate SUB, e.g., in the third direction DR3. The first source regions S1 of the first active layers ACT1 may be disposed on first sides of the first channel regions CHA1, and the first drain regions D1 of the first active layers ACT1 may be disposed on second sides of the first channel regions CHA1. The first source regions S1 and the first drain regions D1 may be areas that do not overlap the first gate electrodes G1 in the third direction DR3. The first source regions S1 and the first drain regions D1 may be areas that are formed by doping a silicon semiconductor or an oxide semiconductor with ions and thus have conductivity.

A first gate insulating film 131 may be disposed on the first active layers ACT1 of the first TFTs “TFT1”. The first gate insulating film 131 may be formed as an inorganic film such as a silicon nitride layer, a silicon oxynitride layer, a silicon oxide layer, a titanium oxide layer, or an aluminum oxide layer.

A first gate metal layer GTL1 may be disposed on the first gate insulating film 131. The first gate metal layer GTL1 may include the first gate electrodes G1 of the first TFTs “TFT1” and first capacitor electrodes CAE1. The first gate electrodes G1 may overlap the first active layers ACT1 in the third direction DR3. FIG. 7 illustrates that the first gate electrodes G1 and the first capacitor electrodes CAE1 are spaced apart from one another, but the first gate electrodes G1 and the first capacitor electrodes CAE1 may be connected to each other. The first gate metal layer GTL1 may be formed as a single-layer film or a multilayer film including any one of molybdenum (Mo), aluminum (Al), chromium (Cr), gold (Au), titanium (Ti), nickel (Ni), neodymium (Nd), copper (Cu), or an alloy thereof.

A second gate insulating film 132 may be disposed on the first gate electrodes G1 of the first TFTs “TFT1” and the first capacitor electrodes CAE1. The second gate insulating film 132 may be formed as an inorganic film such as a silicon nitride layer, a silicon oxynitride layer, a silicon oxide layer, a titanium oxide layer, or an aluminum oxide layer.

A second gate metal layer GTL2 may be disposed on the second gate insulating film 132. The second gate metal layer GTL2 may include second capacitor electrodes CAE2. The second capacitor electrodes CAE2 may overlap the first capacitor electrodes CAE1 in the third direction DR3. As the second gate insulating film 132 has a predetermined dielectric constant, capacitors (e.g., “C1” of FIG. 5) may be formed by the first capacitor electrodes CAEL1, the second capacitor electrodes CAE2, and the second gate insulating film 132 between the first capacitor electrodes CAE1 and the second capacitor electrodes CAE2. The second gate metal layer GTL2 may be formed as a single-layer film or a multilayer film including any one of Mo, Al, Cr, Au, Ti, Ni, Nd, Cu, or an alloy thereof.

A first interlayer insulating film 141 may be disposed on the second capacitor electrodes CAE2. The first interlayer insulating film 141 may be formed as an inorganic film such as a silicon nitride layer, a silicon oxynitride layer, a silicon oxide layer, a titanium oxide layer, or an aluminum oxide layer.

Second TFTs “TFT2” may be disposed on the first interlayer insulating film 141. The second TFTs “TFT2” may correspond to one of the first and third transistors ST1 and ST3 of FIG. 5. Each of the second TFTs “TFT2” may include a second active layer ACT2 and a second gate electrode G2.

The second active layers ACT2 of the second TFTs “TFT2” may be disposed on the first interlayer insulating film 141. The second active layers ACT2 may include an oxide semiconductor. For example, the second active layers ACT2 may include indium gallium zinc oxide (IGZO), indium gallium zinc tin oxide (IGZTO), or indium gallium tin oxide (ITO).

Each of the second active layers ACT2 may include a second channel region CHA2, a second source region S2, and a second drain region D2. The second channel regions CHA2 of the second active layers ACT2 may be areas that overlap the second gate electrodes G2 in the third direction DR3. The second source regions S2 of the second active layers ACT2 may be disposed on first sides of the second channel regions CHA2, and the second drain regions D2 of the second active layers ACT2 may be disposed on the other side of the second channel region CHA2. The second source regions S2 and the second drain regions D2 may be areas that do not overlap the second gate electrodes G2 in the third direction DR3. The second source regions S2 and the second drain regions D2 may be areas that are formed by doping an oxide semiconductor or an oxide semiconductor with ions and thus have conductivity.

A third gate insulating film 133 may be disposed on the second active layers ACT2 of the second TFTs “TFT2”. The third gate insulating film 133 may be formed as an inorganic film such as a silicon nitride layer, a silicon oxynitride layer, a silicon oxide layer, a titanium oxide layer, or an aluminum oxide layer.

A third gate metal layer GTL3 may be disposed on the third gate insulating film 133. The third gate metal layer GTL3 may include the second gate electrodes G2 of the second TFTs “TFT2”. The second gate electrodes G2 may overlap the second active layers ACT2 in the third direction DR3. The third gate metal layer GTL3 may be formed as a single-layer film or a multilayer film including any one of Mo, Al, Cr, Au, Ti, Ni, Nd, Cu, or an alloy thereof.

A second interlayer insulating film 142 may be disposed on the second gate electrode G2 of the second TFT “TFT2”. The second interlayer insulating film 142 may be formed as an inorganic film such as, a silicon nitride layer, a silicon oxynitride layer, a silicon oxide layer, a titanium oxide layer, or an aluminum oxide layer.

A first data metal layer DTL1 may be disposed on the second interlayer insulating film 142. The first data metal layer DTL1 may include first pixel connecting electrodes PCE1, first connecting electrodes BE1, and second connecting electrodes BE2. The first pixel connecting electrodes PCE1 may be connected (e.g., electrically connected) to the first drain regions D1 of the first active layers ACT1 through first pixel connecting holes PCT1, which penetrate (or are formed in) the first gate insulating film 131, the second gate insulating film 132, the first interlayer insulating film 141, the third gate insulating film 133, and the second interlayer insulating film 142. The first connecting electrodes BE1 may be connected (e.g., electrically connected) to the second source regions S2 of the second active layers ACT2 through first connecting contact holes BCT1, which penetrate (or are formed in) the second interlayer insulating film 142. The second connecting electrodes BE2 may be connected (e.g., electrically connected) to the second drain regions D2 of the second active layers ACT2 through second connecting contact holes BCT2, which penetrate (or are formed in) the second interlayer insulating film 142. The first data metal layer DTL1 may be formed as a single-layer film or a multilayer film including any one of Mo, Al, Cr, Au, Ti, Ni, Nd, Cu, or an alloy thereof. For example, the first data metal layer DTL1 may include a first layer formed of Ti, a second layer formed of Al, and a third layer formed of Ti.

A first organic film 160, which is for planarizing or flattening any height differences formed by the first TFTs “TFT1” and the second TFTs “TFT2”, may be disposed on the first pixel connecting electrodes PCE1, the first connecting electrodes BE1, and the second connecting electrodes BE2. The first organic film 160 may be formed as an organic film including an acrylic resin, an epoxy resin, a phenolic resin, a polyamide resin, or a polyimide resin.

A second data metal layer DTL2 may be disposed on the first organic film 160. The second data metal layer DTL2 may include second pixel connecting electrodes PCE2. The second pixel connecting electrodes PCE2 may be connected (e.g., electrically connected) to the first pixel connecting electrodes PCE1 through second pixel connecting holes PCT2, which penetrate (or are formed in) the first organic film 160. The second data metal layer DTL2 may be formed as a single-layer film or a multilayer film including any one of Mo, Al, Cr, Au, Ti, Ni, Nd, Cu, or an alloy thereof. For example, the second data metal layer DTL2 may include a first layer formed of Ti, a second layer formed of Al, and a third layer formed of Ti.

A second organic film 180 may be disposed on the second pixel connecting electrodes PCE2. The second organic film 180 may be formed as an organic film including an acrylic resin, an epoxy resin, a phenolic resin, a polyamide resin, or a polyimide resin.

The light-emitting element layer EML may be disposed on the second organic film 180. The light-emitting element layer EML may include the pixel electrodes PXE, light-emitting elements LE1, LE2, and LE3, a common electrode CE, and a planarization film 190.

A pixel electrode layer PXL may be disposed on the second organic film 180. The pixel electrode layer PXL may include the pixel electrodes PXE. The pixel electrodes PXE may be connected (e.g., electrically connected) to the second pixel connecting electrodes PCE2 through third pixel connecting holes CT3, which penetrate (or are formed in) the second organic film 180. Accordingly, the pixel electrodes PXE may be connected (e.g., electrically connected) to the first source or drain regions S1 or D1 of the first TFTs “TFT1” through the first pixel connecting electrodes PCE1 or the second pixel connecting electrodes PCE2. Thus, pixel voltages or anode voltages, which are controlled by the first or second TFTs “TFT1” or “TFT2”, may be applied to the pixel electrodes PXE.

The pixel electrode layer PXL may be formed as a single-layer film or a multilayer film including any one of Mo, Al, Cr, Au, Ti, Ni, Nd, Cu, or an alloy thereof. As the pixel electrodes PXE are bonded to first, second, and third light-emitting elements LE1, LE2, and LE3, the surface resistance of the pixel electrodes PXE may be lowered to reduce the contact resistance between the pixel electrodes PXE and the first, second, and third light-emitting elements LE1, LE2, and LE3. For example, the pixel electrode layer PXL may be formed of Cu with a low surface resistance.

The first, second, and third light-emitting elements LE1, LE2, and LE3 may be disposed on the pixel electrodes PXE. The first, second, and third light-emitting elements LE1, LE2, and LE3 may be, for example, vertical microLEDs extending in the third direction DR3.

The first, second, and third light-emitting elements LE1, LE2, and LE3 may be formed of an inorganic material such as GaN. The first, second, and third light-emitting elements LE1, LE2, and LE3 may have a length in the range of several to hundreds of micrometers in the first, second, and third directions DR1, DR2, and DR3. For example, the first, second, and third light-emitting elements LE1, LE2, and LE3 may have a length of about 100 μm or less.

The first, second, and third light-emitting elements LE1, LE2, and LE3 may be grown from a semiconductor substrate such as a silicon wafer. The first, second, and third light-emitting elements LE1, LE2, and LE3 may be moved from the silicon wafer onto the pixel electrodes PXE on the substrate SUB. In another example, the first, second, and third light-emitting elements LE1, LE2, and LE3 may be moved onto the pixel electrodes PXE on the substrate SUB in an electrostatic manner using an electrostatic head or through stamping using an elastic polymer material such as polydimethylsiloxane (PDMS) or silicone.

Each of the first, second, and third light-emitting elements LE1, LE2, and LE3 may include a contact electrode CTE, a first semiconductor layer SEM1, an electron blocking layer EBL, an active layer MQW, a superlattice layer SLT, and a second semiconductor layer SEM2.

The contact electrode CTE may be disposed on the pixel electrodes PXE. The contact electrode CTE and the pixel electrodes PXE may be bonded together via an ACF or an anisotropic conductive paste (ACP). In another example, the contact electrode CTE and the pixel electrodes PXE may be bonded together by soldering. For example, the contact electrode CTE may include at least one of Au, Cu, Al, and Sn.

The first semiconductor layers SEM1 of the first, second, and third light-emitting elements LE1, LE2, and LE3 may be disposed on the contact electrode CTE. The first semiconductor layers SEM1 may be formed of GaN doped with a p-type dopant such as magnesium (Mg), zinc (Zn), calcium (Ca), selenium (Se), or barium (Ba).

The electron blocking layers EBL of each of the first, second, and third light-emitting elements LE1, LE2, and LE3 may be disposed on the first semiconductor layers SEM1. The electron blocking layers EBL may be a layer for suppressing or preventing too many electrons from flowing toward the active layers MQW. For example, the electron blocking layers EBL may include p-AlGaN doped with Mg, which is a p-type dopant. In some embodiments, the electron blocking layers EBL may not be provided.

The active layers MQW of each of the first, second, and third light-emitting elements LE1, LE2, and LE3 may be disposed on the electron blocking layers EBL. As electron-hole pairs are combined in response to electrical signals being applied through the first semiconductor layers SEM1 and the second semiconductor layers SEM2, the active layers MQW may emit light.

The active layers MQW may include a material having a single-quantum well structure or a multi-quantum well structure. In a case where the active layers MQW include a material having a multi-quantum well structure, the active layers MQW may have a structure in which well layers and barrier layers are alternately stacked each other. Here, the well layers may be formed of InGaN, and the barrier layers may be formed of GaN or AlGaN. However, embodiments are not limited thereto. In another example, the active layers MQW may have a structure in which semiconductor materials having a large bandgap energy and semiconductor materials having a small bandgap energy are alternately stacked each other or may include a group III semiconductor material or a group V semiconductor material depending on the wavelength range of light to be emitted by the active layers MQW.

In a case where the active layers MQW include InGaN, the color of light emitted by the active layers MQW may vary according to the content of the indium (In) of the active layers MQW. For example, the greater the content of In of the active layers MQW, the more the light emitted by the active layers MQW may be moved to a red wavelength range, and the less the content of In of the active layers MQW, the more the light emitted by the active layers MQW may be moved to a blue wavelength range. Thus, the content of In of the active layer MQW of the first light-emitting element LE1, which emits the first light, e.g., red-wavelength light, may be greater than the content of In of the active layer MQW of the second light-emitting element LE2, and the content of In of the active layer MQW of the second light-emitting element LE2 may be greater than the content of In of the active layer MQW of the active layer MQW of the third light-emitting element LE3. For example, the content of In of the active layer MQW of the first light-emitting element LE1 may be about 30 wt % to about 40 wt %, the content of In of the active layer MQW of the second light-emitting element LE2 may be about 20 wt % to about 30 wt %, and the content of In of the active layer MQW of the active layer MQW of the third light-emitting element LE3 may be about 10 wt % to about 20 wt %. For example, the active layer MQW of the first light-emitting element LE1 may emit the first light, the active layer MQW of the second light-emitting element LE2 may emit the second light, and the active layer MQW of the third light-emitting element LE3 may emit the third light.

The superlattice layers SLT of the first, second, and third light-emitting elements LE1, LE2, and LE3 may be disposed on the active layers MQW. The superlattice layers SLT may alleviate or reduce the stress between the second semiconductor layers SEM2 and the active layers MQW. For example, the superlattice layers SLT may be formed of InGaN or GaN. The superlattice layers SLT may not be provided or formed.

The second semiconductor layers SEM2 may be disposed on the superlattice layers SLT. The second semiconductor layers SEM2 may be doped with a dopant of a second conductivity type such as silicon (Si), germanium (Ge), or tin (Sn). For example, the second semiconductor layers SEM2 may include n-GaN doped with Si, which is an n-type dopant.

The planarization film 190 may be disposed on the sides of each of the first, second, and third light-emitting elements LE1, LE2, and LE3. The planarization film 190 may be a layer for planarizing or flattening any height differences formed by the first, second, and third light-emitting elements LE1, LE2, and LE3. The top surfaces (or upper surfaces) of the first, second, and third light-emitting elements LE1, LE2, and LE3 and the top surface of the planarization film 190 may be connected to one another to be flat. The planarization film 190 may be formed as an organic film including an acrylic resin, an epoxy resin, a phenolic resin, a polyamide resin, or a polyimide resin.

The common electrode CE may be disposed on the top surfaces (or upper surfaces) of the first, second, and third light-emitting elements LE1, LE2, and LE3 and the top surface (or upper surfaces) of the planarization film 190. The common electrode CE may be a common layer formed in common in first, second, and third subpixels SPX1, SPX2, and SPX3. The common electrode CE may be formed of a transparent conductive oxide (TCO) capable of transmitting light therethrough, such as ITO or IZO.

Referring to FIGS. 7 and 8, as the pixel electrodes PXE are bonded to the first, second, and third light-emitting elements LE1, LE2, and LE3, the contact resistance between the pixel electrodes PXE and the first, second, and third light-emitting elements LE1, LE2, and LE3 may be reduced in cast that the pixel electrodes PXE are formed of Cu with a low surface resistance.

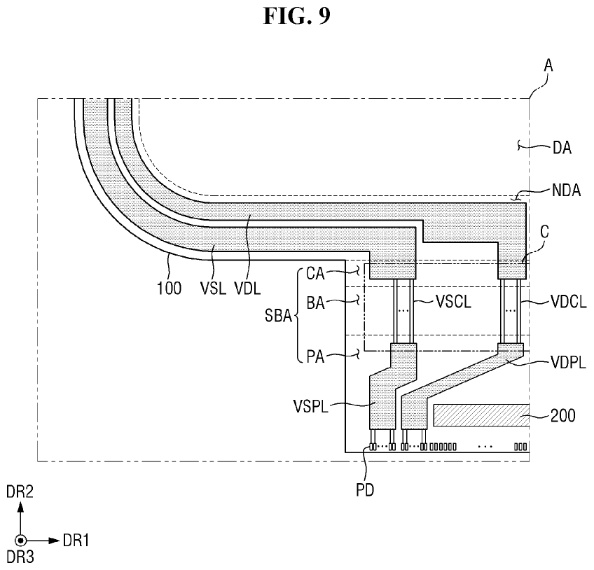

FIG. 9 is a schematic layout view of an area A of FIG. 2.

FIG. 9 illustrates first power supply lines VDL, second power supply lines VSL, first power supply connecting lines VDCL, second power supply connecting lines VSCL, first power supply pad lines VDPL, and a second power supply pad lines VSPL.

Referring to FIG. 9, the first power supply lines VDL may be disposed in the non-display area NDA and the connecting area CA. The first power supply lines VDL may be disposed in parts of the non-display area NDA adjacent to the left, lower, and right sides of the display area DA of the display panel 100. The first power supply lines VDL may extend in the first direction DR1, and disposed in the part of the non-display area NDA adjacent to the lower side of the display area DA of the display panel 100. The first power supply lines VDL may extend in the second direction DR2, in the connecting area CA. The first power supply lines VDL may be bent in the first direction DR1 from the second direction DR2, in the part of the non-display area NDA adjacent to the lower side of the display area DA of the display panel 100.

The first power supply lines VDL may be disposed in the parts of the non-display area NDA adjacent to the lower and left sides of the display area DA of the display panel 100 and in part of the non-display area NDA at the lower left corner of the display panel 100. Also, the first power supply lines VDL may be disposed in the parts of the non-display area NDA adjacent to the lower and right sides of the display area DA of the display panel 100 and in part of the non-display area NDA at the lower right corner of the display panel 100. Also, the first power supply lines VDL may be disposed in part of the non-display area NDA adjacent to the upper side of the display area DA of the display panel 100 and in parts of the non-display area NDA adjacent to the upper-left and upper-right corners of the display panel 100.

The second power supply lines VSL may be disposed in the non-display area NDA and the connecting area CA. The second power supply lines VSL may be disposed in the parts of the left, lower, and right sides of the display area DA of the display panel 100. The second power supply lines VSL may extend in the first direction DR1, and may be disposed in the part of the non-display area NDA adjacent to the lower side of the display area DA of the display panel 100. The second power supply lines VSL may extend in the second direction DR2, and may be disposed in the connecting area CA. The second power supply lines VSL may be bent in the first direction DR1 from the second direction DR2, in the part of the non-display area NDA adjacent to the lower side of the display area DA of the display panel 100.

The second power supply lines VSL may be disposed in the parts of the non-display area NDA adjacent to the lower and left sides of the display area DA of the display panel 100 and in the part of the non-display area NDA at the lower left corner of the display panel 100. Also, the second power supply lines VSL may be disposed in the parts of the non-display area NDA adjacent to the lower and right sides of the display area DA of the display panel 100 and in the part of the non-display area NDA at the lower right corner of the display panel 100. Also, the second power supply lines VSL may be disposed in part of the non-display area NDA adjacent to the upper side of the display area DA of the display panel 100 and in the parts of the non-display area NDA adjacent to the upper-left and upper-right corners of the display panel 100.

The second power supply lines VSL may be disposed closer to the edges of the display panel 100 than the first power supply lines VDL in the non-display area NDA. The width of the second power supply lines VSL may be greater than the width of the first power supply lines VDL, in the non-display area NDA.

The first power supply connecting lines VDCL may be disposed in the bending area BA. The first power supply connecting lines VDCL may be connected to the first power supply lines VDL, in the connecting area CA. The first power supply connecting lines VDCL may be connected to the first power supply pad lines VDPL, in the pad area PA. For example, to prevent cracks in lines in case that the display panel 100 is bent in the bending area BA, the first power supply lines VDL and the first power supply pad lines VDPL may be connected to the first power supply connecting lines VDCL, which have a relatively small width in the bending area BA.

The second power supply connecting lines VSCL may be disposed in the bending area BA. The second power supply connecting lines VSCL may be connected to the second power supply lines VSL, in the connecting area CA. The second power supply connecting lines VSCL may be connected to the second power supply pad lines VSPL, in the pad area PA. For example, to prevent cracks in lines in case that the display panel 100 is bent in the bending area BA, the second power supply lines VSL and the second power supply pad lines VSPL may be connected to the second power supply connecting lines VSCL, which have a relatively small width in the bending area BA.

The first power supply pad lines VDPL may be disposed in the pad area PA. The first power supply pad lines VDPL may be connected to the pads PD on the lower edge of the pad area PA.

The second power supply pad lines VSPL may be disposed in the pad area PA. The second power supply pad lines VSPL may be connected to the pads PD on the lower edge of the pad area PA. The second power supply pad lines VSPL may be disposed closer to the left edge of the display panel 100 than the first power supply pad lines VDPL. The second power supply pad lines VSPL may be disposed to bypass the display driving circuit 200.

FIG. 10 is a schematic layout view of an area C of FIG. 9.

Referring to FIG. 10, scan fan-out lines SFL, data fan-out lines DFL, the first power supply lines VDL, and the second power supply lines VSL may be disposed in the connecting area CA. Scan connecting lines SCL, data connecting lines DCL, the first power supply connecting lines VDCL, and the second power supply connecting lines VSCL may be disposed in the bending area BA. Scan pad lines SPL, data pad lines DPL, the first power supply pad lines VDPL, and the second power supply pad lines VSPL may be disposed in the pad area PA.

Each of the first power supply lines VDL may include first, second, and third sub-power supply lines VDL1, VDL2, and VDL3. The first, second, and third sub-power supply lines VDL1, VDL2, and VDL3 may overlap one another in the third direction DR3. The second sub-power supply line VDL2 may be connected (e.g., electrically connected) to the first sub-power supply line VDL1 through a first power supply hole VPH1. The third sub-power supply line VDL3 may be disposed on the second sub-power supply line VDL2.

Each of the first power supply pad lines VDPL may include first, second, and third sub-power supply pad lines VDPL1, VDPL2, and VDPL3. The first, second, and third sub-power supply pad lines VDPL1, VDPL2, and VDPL3 may overlap one another in the third direction DR3. The second sub-power supply pad line VDPL2 may be connected (e.g., electrically connected) to the first sub-power supply pad line VDPL1 through a first pad contact hole. The third sub-power supply pad line VDPL3 may be disposed on the second sub-power supply pad line VDPL2.

The first power supply connecting lines VDCL may extend from an end of the second sub-power supply line VDL2, in the connecting area CA. The first power supply connecting lines VDCL may extend from an end of the second sub-power supply pad line VDPL2, in the pad area PA. For example, the first power supply connecting lines VDCL, the second sub-power supply line VDL2, and the second sub-power supply pad line VDPL2 may be integral with one another.

Each of the second power supply lines VDL may include fourth, fifth, and sixth sub-power supply lines VSL1, VSL2, and VSL3. The fourth, fifth, and sixth sub-power supply lines VSL1, VSL2, and VSL3 may overlap one another in the third direction DR3. The fifth sub-power supply line VSL2 may be connected (e.g., electrically connected) to the fourth sub-power supply line VSL1 through a second power supply hole VPH2. The sixth sub-power supply line VSL3 may be disposed on the fifth sub-power supply line VSL2.

Each of the second power supply pad lines VSPL may include fourth, fifth, and sixth sub-power supply pad lines VSPL1, VSPL2, and VSPL3. The fourth, fifth, and sixth sub-power supply pad lines VSPL1, VSPL2, and VSPL3 may overlap one another in the third direction DR3. The fifth sub-power supply pad line VSPL2 may be connected (e.g., electrically connected) to the fourth sub-power supply pad line VSPL1 through a second pad contact hole. The sixth sub-power supply pad line VSPL3 may be disposed on the fifth sub-power supply pad line VSPL2.

The second power supply connecting lines VSCL may extend from an end of the fifth sub-power supply line VSL2, in the connecting area CA. The second power supply connecting lines VSCL may extend from an end of the fifth sub-power supply pad line VSPL2, in the pad area PA. For example, the second power supply connecting lines VSCL, the fifth sub-power supply line VSL2, and the fifth sub-power supply pad line VSPL2 may be integral with one another.

The scan fan-out lines SFL may overlap the second power supply lines VSL, in the connecting area CA. The data fan-out lines DFL may not overlap the first power supply lines VDL and the second power supply lines VSL, in the connecting area CA.

Each of the scan fan-out lines SFL may include first and second scan fan-out lines SFL1 and SFL2, which overlap each other in the third direction DR3 (or a Z-axis direction). The second scan fan-out line SFL2 may be connected (e.g., electrically connected) to the first scan fan-out line SFL1 through a first scan connecting hole SCH1.

Each of the scan pad lines SPL may include first and second scan pad lines SPL1 and SPL2, which overlap each other in the third direction DR3 (or the Z-axis direction). The second scan pad line SPL2 may be connected (e.g., electrically connected) to the second scan fan-out line SFL2 through a second scan connecting hole SCH2.

The scan connecting lines SCL may be connected (e.g., electrically connected) to the first scan fan-out lines SFL1 of the scan fan-out lines SFL through third scan connecting holes SCH3, in the connecting area CA. The scan connecting lines SCL may be connected (e.g., electrically connected) to the first scan pad lines SPL1 of the scan pad lines SPL through fourth scan connecting holes SCH4.

The data connecting lines DCL may be connected (e.g., electrically connected) to the data fan-out lines DFL through first data connecting holes DCH1, in the connecting area CA. The data connecting lines DCL may be connected (e.g., electrically connected) to the data pad lines DPL through second data connecting holes DCH2, in the pad area PA.

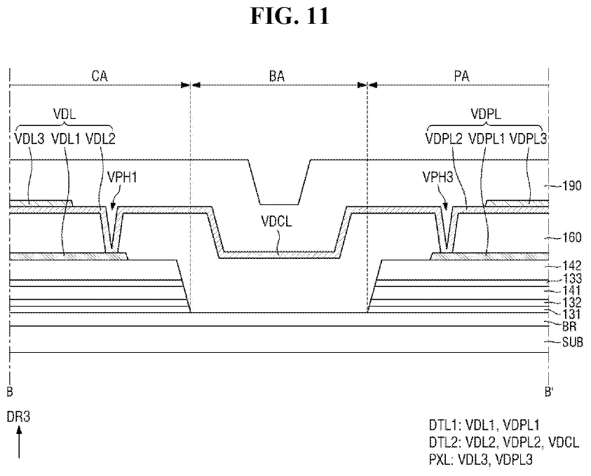

FIG. 11 is a schematic cross-sectional view taken along line B-B′ of FIG. 10.

Referring to FIG. 11, a first sub-power supply line VDL1 of a first power supply line VDL may be disposed on the second interlayer insulating film 142, a second sub-power supply line VDL2 of the first power supply line VDL may be disposed on the first organic film 160, and a third sub-power supply line VDL3 of the first power supply line VDL may be disposed on the second sub-power supply line VDL2. The second sub-power supply line VDL2 may be connected (e.g., electrically connected) to the first sub-power supply line VDL1 through the first power supply hole VPH1, which penetrates (or is formed in) the first organic film 160. The first, second, and third sub-power supply lines VDL1, VDL2, and VDL3 may overlap one another in the third direction DR3.

A first sub-power supply pad line VDPL1 of a first power supply pad line VDPL may be disposed on the second interlayer insulating film 142, a second sub-power supply pad line VDPL2 of the first power supply pad line VDPL may be disposed on the first organic film 160, and a third sub-power supply pad line VDPL3 of the first power supply pad line VDPL may be disposed on the second sub-power supply pad line VDPL2. The second sub-power supply pad line VDPL2 may be connected (e.g., electrically connected) to the first sub-power supply pad line VDPL1 through a third power supply hole VPH3, which penetrates (or is formed in) the first organic film 160. The first, second, and third sub-power supply pad lines VDPL1, VDPL2, and VDPL3 may overlap one another in the third direction DR3.

A first power supply connecting line VDCL may be disposed on the first organic film 160. The first power supply connecting line VDCL may be integral with the second sub-power supply line VDL2 and the second sub-power supply pad line VDPL2. For example, the first power supply connecting line VDCL may be bended or recessed toward the substrate SUB in the bending area BA.

For example, the first data metal layer DTL1 may include the first sub-power supply line VDL1 and the first sub-power supply pad line VDPL1. The second data metal layer DTL2 may include the second sub-power supply line VDL2, the second sub-power supply pad line VDPL2, and the first power supply connecting line VDCL. The pixel electrode layer PXL may include the third sub-power supply line VDL3 and the third sub-power supply pad line VDPL3.

As the microLEDs of a microLED display device are formed of an inorganic material, the microLED display device, as compared with an OLED display device, may not require an encapsulation film for encapsulating an organic light-emitting layer, and thus, dams for preventing the spillover of an organic film of the encapsulation film may not be required. Accordingly, in the microLED display device, the second organic film 180 may be disposed in the display area DA, but not in the non-display area NDA. Therefore, the third sub-power supply line VDL3 may be disposed on the second sub-power supply line VDL2, and the top surface (or upper surface) of the second sub-power supply line VDL2 and the bottom surface (or lower surface) of the third sub-power supply line VDL3 may be in contact (e.g., direct contact) with each other. Also, the third sub-power supply pad line VDPL3 may be disposed on the second sub-power supply pad line VDPL2, and the top surface (or upper surface) of the second sub-power supply pad line VDPL2 and the bottom surface (or lower surface) of the third sub-power supply pad line VDPL3 may be in contact (e.g., direct contact) with each other. Also, as the planarization film 190 is disposed in both the display area DA and the non-display area NDA, the planarization film 190 may be disposed on the third sub-power supply line VDL3 and the third sub-power supply pad line VDPL3. The planarization film 190 may be removed from the bending area BA. For example, the planarization film 190 may be partially removed from the bending area BA to have a recessed portion that is recessed toward the substrate SUB and extends in the first direction DR1.

As illustrated in FIG. 11, as the first power supply line VDL includes the first, second, and third sub-power supply line VDL1, VDL2, and VDL3, which are disposed in three different layers, the area of the first power supply line VDL may be increased. Also, as the third sub-power supply line VDL3 is formed of a metallic material with a low surface resistance such as Cu, the resistance of the first power supply line VDL may be lowered, the width of the first power supply line VDL in the non-display area NDA may be reduced, and as a result, the width of the non-display area NDA may be reduced. Also, ripples (or coupling noise) that may be caused by voltage variations between the first power supply line VDL and other lines overlapping the first power supply line VDL may be minimized.

Also, as the first power supply pad line VDPL includes the first, second, and third sub-power supply pad lines VDPL1, VDPL2, and VDPL3, which are disposed in three different layers, the area of the first power supply pad line VDPL may be increased. Also, as the third sub-power supply pad line VDPL3 may be formed of a metallic material with a low surface resistance such as Cu, the resistance of the first power supply pad line VDPL may be lowered, the width of the first power supply pad line VDPL in the non-display area NDA may be reduced, and as a result, the width of the non-display area NDA may be reduced. Also, ripples (or coupling noise) that may be caused by voltage variations between the first power supply pad line VDPL and other lines overlapping the first power supply pad line VDPL may be minimized.

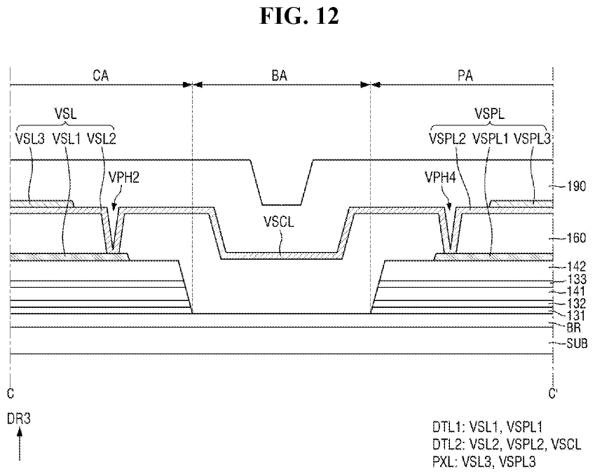

FIG. 12 is a schematic cross-sectional view taken along line C-C′ of FIG. 10.

Referring to FIG. 12, a fourth sub-power supply line VSL1 of a second power supply line VSL may be disposed on the second interlayer insulating film 142, a fifth sub-power supply line VSL2 of the second power supply line VSL may be disposed on the first organic film 160, and a sixth sub-power supply line VSL3 of the second power supply line VSL may be disposed on the fifth sub-power supply lien VSL2. The fifth sub-power supply line VSL2 may be connected (e.g., electrically connected) to the fourth sub-power supply line VSL1 through the second power supply hole VPH2, which penetrates (or is formed in) the first organic film 160. The fourth, fifth, and sixth sub-power supply lines VSL1, VSL2, and VSL3 may overlap one another in the third direction DR3.

A fourth sub-power supply pad line VSPL1 of a second power supply pad line VSPL may be disposed on the second interlayer insulating film 142, a fifth sub-power supply pad line VSPL2 of the second power supply pad line VSPL may be disposed on the first organic film 160, and a sixth sub-power supply pad line VSPL3 of the second power supply pad line VSPL may be disposed on the fifth sub-power supply pad line VSPL2. The fifth sub-power supply pad line VSPL2 may be connected (e.g., electrically connected) to the fourth sub-power supply pad line VSPL1 through a fourth power supply hole VPH4, which penetrates (or is formed in) the first organic film 160. The fourth, fifth, and sixth sub-power supply pad lines VSPL1, VSPL2, and VSPL3 may overlap one another in the third direction DR3.

A second power supply connecting line VSCL may be disposed on the first organic film 160. The second power supply connecting line VSCL may be integral with the second sub-power supply line VDL2 and the second sub-power supply pad line VDPL2.

For example, the first data metal layer DTL1 may include the fourth sub-power supply line VSL1 and the fourth sub-power supply pad line VSPL1. The second data metal layer DTL2 may include the fifth sub-power supply line VSL2, the fifth sub-power supply pad line VSPL2, and the second power supply connecting line VSCL. The pixel electrode layer PXL may include the sixth sub-power supply line VSL3 and the sixth sub-power supply pad line VSPL3.

In a microLED display device, the second organic film 180 may be disposed in the display area DA, but not in the non-display area NDA. Thus, the sixth sub-power supply line VSL3 may be disposed on the fifth sub-power supply line VSL2, and the top surface (or upper surface) of the fifth sub-power supply line VSL2 and the bottom surface (or lower surface) of the sixth sub-power supply line VSL3 may be in contact (e.g., directly contact) with each other. Also, the sixth sub-power supply pad line VSPL3 may be disposed on the fifth sub-power supply pad line VSPL2, and the top surface (or upper surface) of the fifth sub-power supply pad line VSPL2 and the bottom surface (or lower surface) of the sixth sub-power supply pad line VSPL3 may be in contact (e.g., directly contact) with each other. Also, as the planarization film 190 is disposed in both the display area DA and the non-display area NDA, the planarization film 190 may be disposed on the sixth sub-power supply line VSL3 and the sixth sub-power supply pad line VSPL3. The planarization film 190 may be removed from the bending area BA. For example, the planarization film 190 may be partially removed from the bending area BA to have a recessed portion that is recessed toward the substrate SUB and extends in the first direction DR1.

As illustrated in FIG. 12, as the second power supply line VSL includes the fourth, fifth, and sixth sub-power supply lines VSL1, VSL2, and VSL3, which are disposed in three different layers, the area of the second power supply line VSL may be increased. Also, as the sixth sub-power supply line VSL3 is formed of a metallic material with a low surface resistance such as Cu, the resistance of the second power supply lines VSL may be lowered, the width of the second power supply lines VSL in the non-display area NDA may be reduced, and as a result, the width of the non-display area NDA may be reduced. Also, ripples (or coupling noise) that may be caused by voltage variations between the second power supply lines VSL and other lines overlapping the second power supply lines VSL may be minimized.

Also, as the second power supply pad line VSPL includes the fourth, fifth, and sixth sub-power supply pad lines VSPL1, VSPL2, and VSPL3, which are disposed in three different layers, the area of the second power supply pad line VSPL may be increased. Also, as the sixth sub-power supply line VSPL3 may be formed of a metallic material with a low surface resistance such as Cu, the resistance of the second power supply pad line VSPL may be lowered, the width of the second power supply pad line VSPL in the non-display area NDA may be reduced, and as a result, the width of the non-display area NDA may be reduced. Also, ripples (or coupling noise) that may be caused by voltage variations between the second power supply pad line VSPL and other lines overlapping the second power supply pad line VSPL may be minimized.

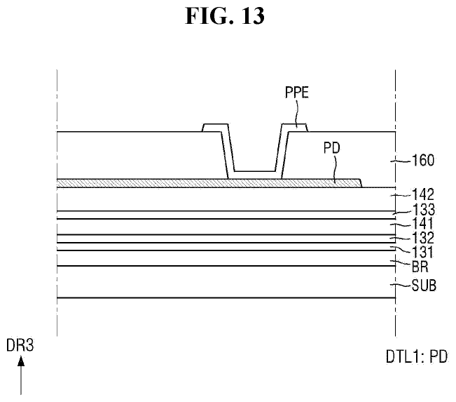

FIG. 13 is a schematic cross-sectional view of a pad of the display panel of FIG. 8.

Referring to FIG. 13, a pad PD may be disposed on the first organic film 160. For example, the second data metal layer DTL2 may include the pad PD.

A pad-shielding electrode PPE may be disposed on the first organic film 160. The pad-shielding electrode PPE may be connected (e.g., electrically connected) to the pad PD through a pad contact hole PDH, which penetrates (or is formed in) the first organic film 160.

The pad-shielding electrode PPE may be a layer for preventing the pad PD from being etched or removed by an etchant during a wet etching process for forming a pixel electrode PXE. Thus, the pad-shielding electrode PPE may be formed of a material that does not react with the etchant during the wet etching process. For example, the pad-shielding electrode PPE may include a TCO such as ITO. The pad-shielding electrode PPE may be formed of poly-ITO, but may also be formed of amorphous ITO in case that the pad-shielding electrode PPE does not react with the etchant during the wet etching process.

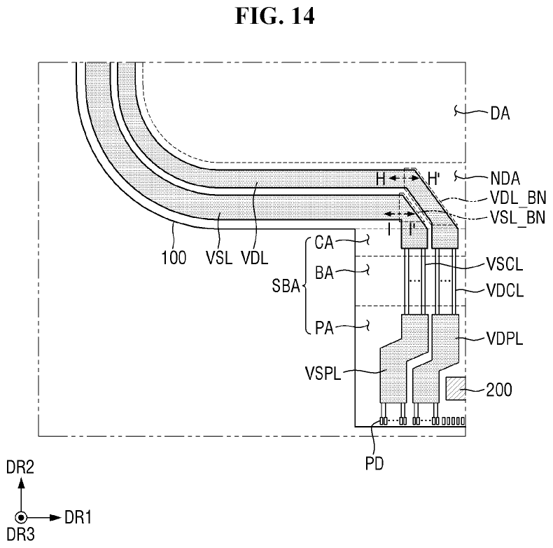

FIG. 14 is a schematic layout view of part B of a display panel of a display device according to an embodiment.

The embodiment of FIG. 14 differs from the embodiment of FIG. 9 in that first and second power supply lines VDL and VSL include first and second bottleneck areas VDL_BN and VSL_BN, respectively, in a non-display area NDA, and will hereinafter be described, focusing on the differences with the embodiment of FIG. 9 for descriptive convenience.

Referring to FIG. 14, the first power supply line VDL may be designed to include the first bottleneck area VDL_BN where the width of the first power supply line VDL is reduced, and the second power supply line VSL may be designed to include the second bottleneck area VSL_BN where the width of the second power supply line VSL is reduced. The first bottleneck area VDL_BN may be an area where the first power supply line VDL is bent in a second direction DR2 from a first direction DR1 in the non-display area NDA. The second bottleneck area VSL_BN may be an area where the second power supply line VSL is bent in the second direction DR2 from the first direction DR1 in the non-display area NDA.

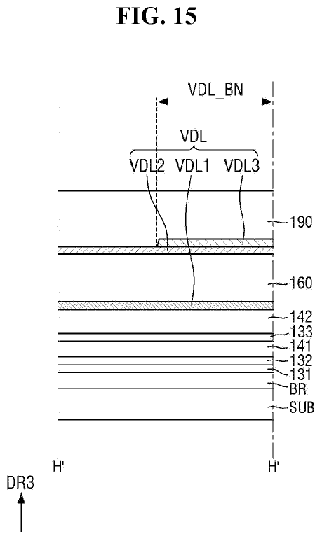

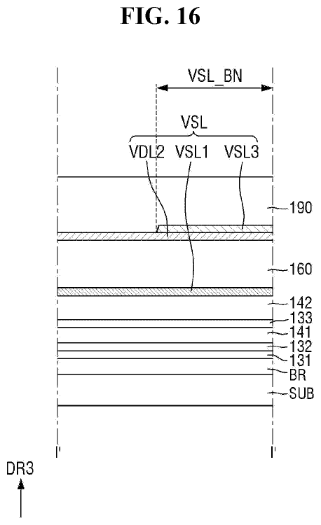

FIG. 15 is a schematic cross-sectional view taken along line H-H′ of FIG. 14. FIG. 16 is a schematic cross-sectional view taken along line I-I′ of FIG. 14.

Referring to FIGS. 15 and 16, to reduce any resistance increase caused by a decrease in the width of a first power supply line VDL in a first bottleneck area VDL_BN, the first power supply line VDL may include first, second, and third sub-power supply lines VDL1, VDL2, and VDL3 in the first bottleneck area VDL_BN and may include only the first and second sub-power supply lines VDL1 and VDL2 in areas other than the first bottleneck area VDL_BN. The first, second, and third sub-power supply lines VDL1, VDL2, and VDL3 are substantially the same as their respective counterparts of FIG. 11, and thus, redundant descriptions thereof will be omitted for descriptive convenience.

Similarly, to reduce any resistance increase caused by a decrease in the width of a second power supply line VSL in a second bottleneck area VSL_BN, the second power supply line VSL may include fourth, fifth, and sixth sub-power supply lines VSL1, VSL2, and VSL3 in the second bottleneck area VSL_BN and may include only the fourth and fifth sub-power supply lines VSL1 and VSL2 in areas other than the second bottleneck area VSL_BN. The fourth, fifth, and sixth sub-power supply lines VSL1, VSL2, and VSL3 are substantially the same as their respective counterparts of FIG. 12, and thus, redundant descriptions thereof will be omitted for descriptive convenience.

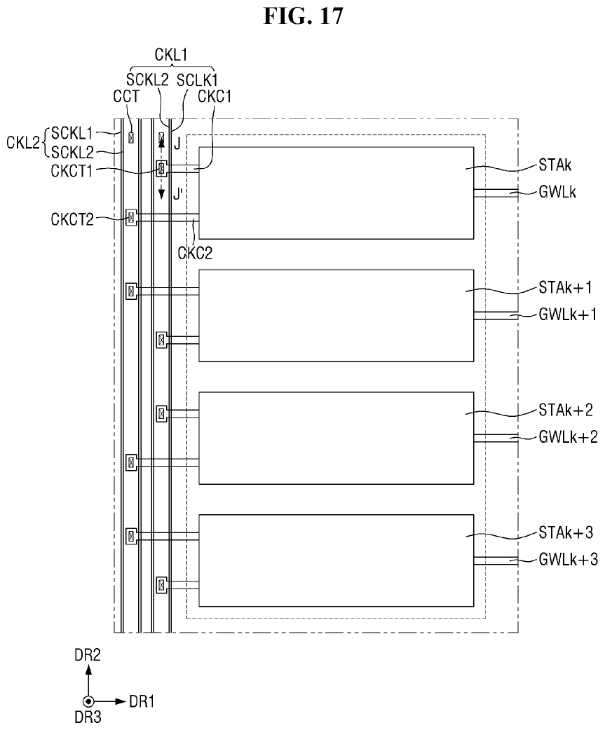

FIG. 17 is a schematic layout view of a first scan driver in a non-display area of the display panel of the display device of FIG. 1.

Referring to FIG. 17, the first scan driver SDC1 may include stages. FIG. 17 illustrates k-th, (k+1)-th, (k+2)-th, and (k+3)-th stages STAk, STAk+1, STAk+2, and STAk+3, which are connected to k-th, (k+1)-th, (k+2)-th, and (k+3)-th write scan lines GWLk, GWLk+1, GWLk+2, and GWLk+3.

The k-th, (k+1)-th, (k+2)-th, and (k+3)-th stages STAk, STAk+1, STAk+2, and STAk+3 may be dependently connected to one another to sequentially output write scan signals to the k-th, (k+1)-th, (k+2)-th, and (k+3)-th write scan lines GWLk, GWLk+1, GWLk+2, and GWLk+3, respectively. Each of the k-th, (k+1)-th, (k+2)-th, and (k+3)-th stages STAk, STAk+1, STAk+2, and STAk+3 may output a write scan signal in accordance with scan clock signals input thereto via first and second scan clock lines CKL1 and CKL2.

Each of the first and second scan clock lines CKL1 and CKL2 may include first and second sub-clock lines SCKL1 and SCKL2. The first and second sub-clock lines SCKL1 and SCKL2 may overlap each other in the third direction DR3. The second sub-clock line SCKL2 may be connected (e.g., electrically connected) to the first sub-clock line SCLK1 through a connecting hole CCT. The first and second scan clock lines CKL1 and CKL2 may be parts of one of the scan fan-out lines SFL of FIG. 10.

The k-th, (k+1)-th, (k+2)-th, and (k+3)-th stages STAk, STAk+1, STAk+2, and STAk+3 may be connected to the first and second scan clock lines CKL1 and CKL2 in an alternate manner through first and second clock connecting lines CKC1 and CKC2. For example, the k-th stage STAk may be connected (e.g., electrically connected) to the first scan clock line CKL1 through the first clock connecting line CKC1 and to the second scan clock line CKL2 through the second clock connecting line CKC2, the (k+1)-th stage STAk+1 may be connected (e.g., electrically connected) to the second scan clock line CKL2 through the first clock connecting line CKC1 and to the first scan clock line CKL1 through the second clock connecting line CKC2, the (k+2)-th stage STAk+2 may be connected to the first scan clock line CKL1 through the first clock connecting line CKC1 and to the second scan clock line CKL2 through the second clock connecting line CKC2, and the (k+3)-th stage STAk+3 may be connected (e.g., electrically connected) to the second scan clock line CKL2 through the first clock connecting line CKC1 and to the first scan clock line CKL1 through the second clock connecting line CKC2.

The first clock connecting line CKC1 may be connected (e.g., electrically connected) to the first or second scan clock line CKL1 or CKL2 through a first clock connecting hole CKCT1. The second clock connecting line CKC2 may be connected (e.g., electrically connected) to the first or second scan clock line CKL1 or CKL2 through a second clock connecting hole CKCT2.

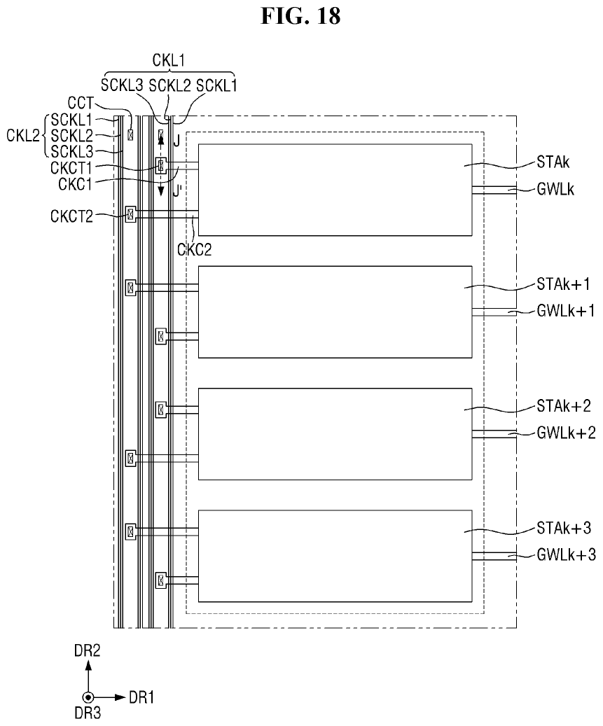

FIG. 18 is a schematic cross-sectional view taken along line J-J′ of FIG. 17.

Referring to FIG. 18, the first sub-clock line SCKL1 of the first scan clock line CKL1 may be disposed on the second interlayer insulating film 142, the second sub-clock line SCKL2 of the first scan clock line CKL1 may be disposed on the first organic film 160. The second sub-clock line SCKL2 may be connected (e.g., electrically connected) to the first sub-clock line SCKL1 through a connecting hole CCT, which penetrates (or is formed in) the first organic film 160.

The first clock connecting line CKC1 may be disposed on the first gate insulating film 131. The first sub-clock line SCKL1 may be connected (e.g., electrically connected) to the first clock connecting line CKC1 through a first clock connecting hole CKCT1, which penetrates (or is formed in) the second gate insulating film 132, the first interlayer insulating film 141, the third gate insulating film 133, and the second interlayer insulating film 142.

The first gate metal layer GTL1 may include the first clock connecting line CKC1. The first data metal layer DTL1 may also include the first sub-clock line SCKL1. The pixel electrode layer PXL may include the second sub-clock line SCKL2.

In a microLED display device, the second organic film 180 may be disposed in the display area DA, but not in the non-display area NDA. Thus, the second sub-clock line SCKL2 may be disposed on the first organic film 160. Also, as the planarization film 190 is disposed in both the display area DA and the non-display area NDA, the planarization film 190 may be disposed on the second sub-clock line SCKL2.

As illustrated in FIG. 18, as each of the first and second clock connecting lines CKC1 and CKC2 includes the first and second sub-clock lines SCKL1 and SCKL2, which are disposed in two different layers, the area of the first and second clock connecting lines CKC1 and CKC2 may be increased. Also, as the second sub-clock line SCKL2 of each of the first clock connecting lines CKC1 and CKC2 is formed of a metallic material with a low surface resistance such as Cu, the resistance of the first and second scan clock lines CKL1 and CKL2 may be lowered, and as a result, the load of write scan signals output to the k-th, (k+1)-th, (k+2)-th, and (k+3)-th write scan lines GWLk, GWLk+1, GWLk+2, and GWLk+3, e.g., an RC delay, may be reduced.

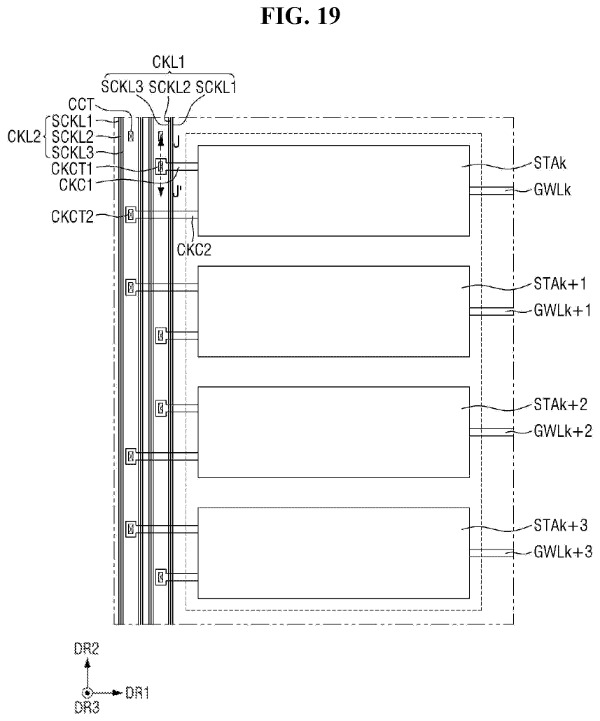

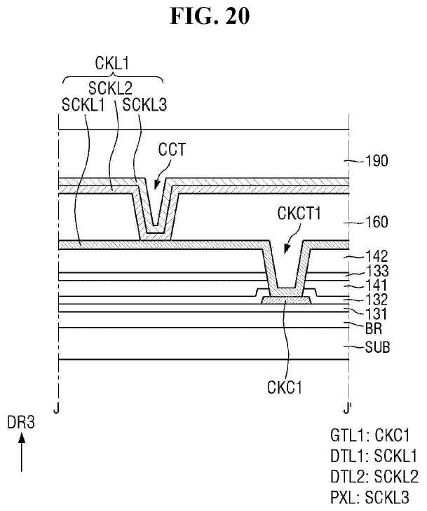

FIG. 19 is a schematic layout view of another example of the first scan driver in the non-display area of the display panel of the display device of FIG. 1. FIG. 20 is a schematic cross-sectional view taken along line K-K′ of FIG. 17.

The embodiment of FIGS. 19 and 20 differs from the embodiment of FIGS. 17 and 18 in that each of first and second scan clock lines CKL1 and CKL2 includes three sub-clock lines.

Referring to FIGS. 19 and 20, each of first and second scan clock lines CKL1 and CKL2 may include first, second, and third sub-clock lines SCKL1, SCKL2, and SCKL3. The first, second, and third sub-clock lines SCKL1, SCKL2, and SCKL3 may overlap one another in the third direction DR3. The second sub-clock line SCKL2 may be connected (e.g., electrically connected) to the first sub-clock line SCKL1 through a connecting hole CCT. The third sub-clock line SCKL3 may be disposed on the second sub-clock line SCKL2.

The first sub-clock line SCKL1 may be disposed on the second interlayer insulating film 142, the second sub-clock line SCKL2 may be disposed on the first organic film 160, and the third sub-clock line SCKL3 may be disposed on the second sub-clock line SCKL2. The second sub-clock line SCKL2 may be connected (e.g., electrically connected) to the first sub-clock line SCKL1 through a connecting hole CCT, which penetrates (or is formed in) the first organic film 160.

The first data metal layer DTL1 may include the first sub-clock line SCKL1. The second data metal layer DTL2 may include the second sub-clock line SCKL2. The pixel electrode layer PXL may include the third sub-clock line SCKL3.

In a microLED display device, the second organic film 180 may be disposed in the display area DA, but not in the non-display area NDA. Thus, the third sub-clock line SCKL3 may be disposed on the first organic film 160, and the top surface (or upper surface) of the second sub-clock line SCKL2 and the bottom surface (or lower surface) of the third sub-clock line SCKL3 may be in contact (e.g., directly contact) with each other. Also, as the planarization film 190 is disposed in both the display area DA and the non-display area NDA, the planarization film 190 may be disposed on the third sub-clock line SCKL3.

As illustrated in FIGS. 19 and 20, as each of the first clock connecting lines CKC1 and CKC2 includes the first, second, and third sub-clock lines SCKL1, SCKL2, and SCKL3, which are disposed in three different layers, the area of the first and second clock connecting lines CKC1 and CKC2 may be increased. Also, as the third sub-clock SCKL3 of each of the first clock connecting lines CKC1 and CKC2 is formed of a metallic material with a low surface resistance such as Cu, the resistance of the first and second scan clock lines CKL1 and CKL2 may be lowered, and as a result, the load of write scan signals output to the k-th, (k+1)-th, (k+2)-th, and (k+3)-th write scan lines GWLk, GWLk+1, GWLk+2, and GWLk+3, e.g., an RC delay, may be reduced.

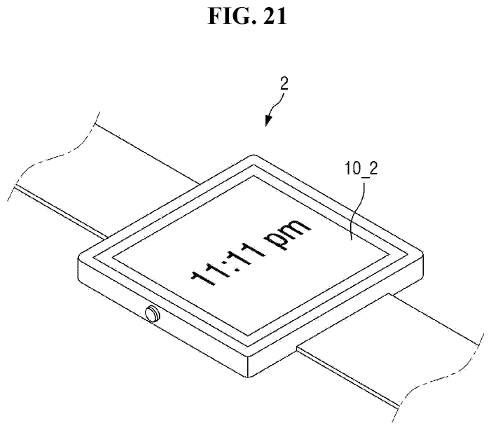

FIG. 21 is a schematic perspective view of a smart device including a display device according to the embodiment of FIG. 1.

Referring to FIG. 21, a display device 10_2 according to the embodiment of FIG. 1 may be applicable to a smart watch 2, which is a type of smart device. The smart watch 2 may generally have a rectangular shape except for a wristband, in a plan view. For example, the planar shape of the display unit of the smart watch 2 may correspond to the planar shape of the display device 10_2.

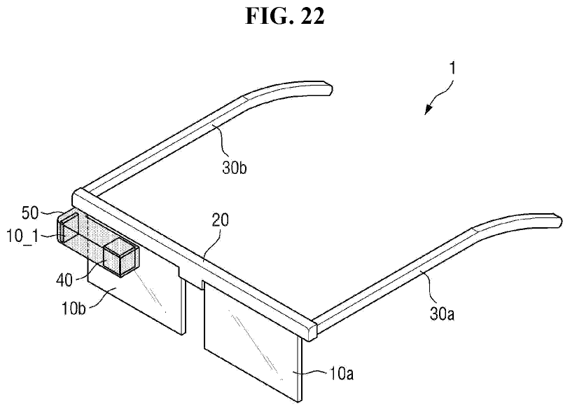

FIG. 22 is a schematic perspective view of a virtual reality (VR) device a display device according to an embodiment. FIG. 22 illustrates a VR device 1, to which a display device 10_1 according to the embodiment of FIG. 1 is applied or implemented.

Referring to FIG. 22, the VR device 1 may be an eyeglass-type device. The VR device 1 may include the display device 10_1, a left-eye lens 10a, a right-eye lens 10b, a support frame 20, eyeglass temples 30a and 30b, a reflective member 40, and a display device storage compartment 50.

FIG. 22 illustrates the VR device 1 including the eyeglass temples 30a and 30b, but the VR device 1 may also be applicable to a head-mounted display (HMD) including a headband that may be worn on the head, instead of the eyeglass temples 30a and 30b. For example, the VR device 1 is not limited to that illustrated in FIG. 29 and may be applicable to various types of electronic devices.

The display device storage compartment 50 may include the display device 10_1 and the reflective member 40. An image displayed by the display device 10_1 may be reflected by the reflective member 40 and may thus be provided to the right eye of a user through the right-eye lens 10b. Thus, the user may view a VR image, displayed by the display device 10_1, by his or her right eye.

FIG. 22 illustrates that the display device storage compartment 50 is disposed at the right end of the support frame 20, but embodiments are not limited thereto. In another example, the display device storage compartment 50 may be disposed at the left end of the support frame 20, in which case, an image displayed by the display device 10_1 may be reflected by the reflective member 40 and may thus be provided to the right eye of the user through the left-eye lens 10a. In still another example, two display device storage compartments 50 may be disposed at both the left and right ends of the support frame 20, in which case, the user may view a VR image, displayed by the display device 10_1, by both his or her left and right eyes.

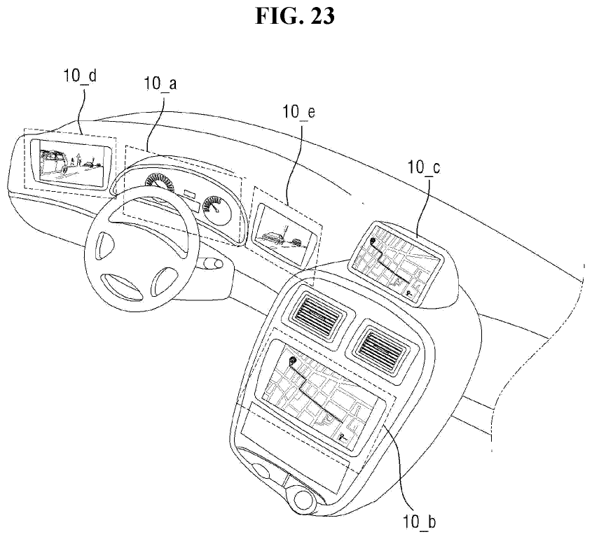

FIG. 23 is a schematic perspective view of a dashboard and a center console of an automobile including display devices according to an embodiment. FIG. 23 illustrates an automobile, to which display devices 10_a, 10_b, 10_c, 10_d, and 10_e according to the embodiment of FIG. 1 are applied or implemented.

Referring to FIG. 23, the display devices 10_a, 10_b, and 10_c may be applicable to the dashboard or center console of an automobile or to a center information display (CID) in the dashboard of an automobile. The display devices 10_d and 10_e may be applicable to room mirror displays that may replace the rear view mirrors of an automobile.

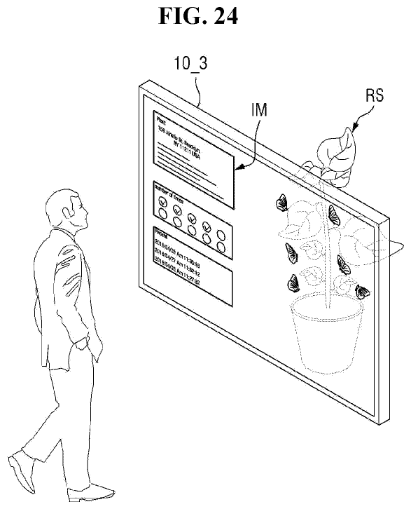

FIG. 24 is a transparent display device including a display device according to an embodiment.

Referring to FIG. 24, a display device 10_3 according to the embodiment of FIG. 1 may be applicable to a transparent display device. The transparent display device may display an image IM and at the same time, transmit light therethrough. Thus, a user at the front of the transparent display device may view not only the image IM on the display device 103, but also an object RS or the background at the rear of the transparent display device. In a case where the display device 10_3 is applied to the transparent display device, a substrate SUB of the display device 10_3 may include light-transmitting parts capable of transmitting light therethrough or may be formed of a material capable of transmitting light therethrough.

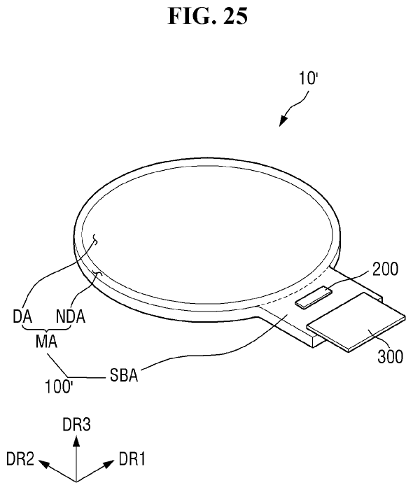

FIG. 25 is a schematic perspective view of a display device 10′ according to an embodiment.

The display device 10′ of FIG. 25 differs from the display device 10 of FIG. 1 only in that a display area DA and a main area MA of a display panel 100′ have a circular shape in a plan view, and thus, a redundant description thereof will be omitted for descriptive convenience.

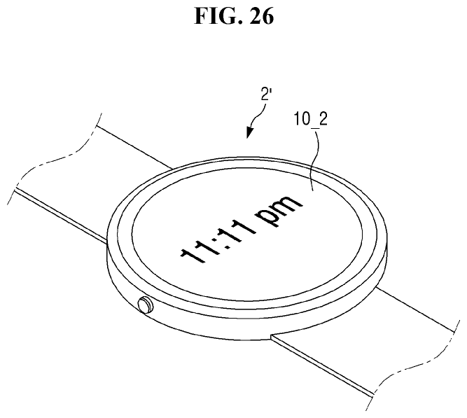

FIG. 26 is a schematic perspective view of a smart device including the display device of FIG. 25.

Referring to FIG. 26, a smart watch 2′ generally has a circular shape except for a wristband. For example, the planar shape of display unit of the smart watch may conform to the planar shape of a display device 10_2.

Although certain embodiments and implementations have been described herein, other embodiments and modifications will be apparent from this description. Accordingly, the invention is not limited to such embodiments, but rather to the broader scope of the appended claims and various obvious modifications and equivalent arrangements as would be apparent to a person of ordinary skill in the art.

What is claimed is:

1. A display device comprising:
a substrate;
an insulating film disposed on the substrate;
a first sub-power supply line disposed on the insulating film and applied by a first power supply voltage;
a first organic film disposed on the first sub-power supply line;
a second sub-power supply line disposed on the first organic film and electrically connected to the first sub-power supply line through a first power supply hole formed in the first organic film;
a third sub-power supply line disposed on the second sub-power supply line;
a pixel electrode disposed on the first organic film;
a light-emitting element disposed on the pixel electrode;
a planarization film disposed on sides of the light-emitting element; and
a common electrode disposed on the light-emitting element and the planarization film, wherein
the planarization film is disposed on the third sub-power supply line.

2. The display device of claim 1, wherein the pixel electrode and the third sub-power supply line include a same material.

3. The display device of claim 1, wherein the pixel electrode and the third sub-power supply line include a material different from a material of the first sub-power supply line and from a material of the second sub-power supply line.

4. The display device of claim 3, wherein
the pixel electrode and the third sub-power supply line include copper (Cu), and
each of the first and second sub-power supply lines includes:
a first layer formed of titanium (Ti),
a second layer formed of aluminum (Al), and
a third layer formed of Ti.

5. The display device of claim 1, wherein an upper surface of the second sub-power supply line is in contact with a lower surface of the third sub-power supply line.

6. The display device of claim 1, further comprising:
a fourth sub-power supply line disposed on the insulating film and applied by a second power supply voltage;
a fifth sub-power supply line disposed on the first organic film and electrically connected to the fourth sub-power supply line through a second power supply hole formed in the first organic film; and
a sixth sub-power supply line disposed on the fifth sub-power supply line.

7. The display device of claim 6, wherein the first power supply voltage is supplied to the common electrode.

8. The display device of claim 6, wherein the planarization film is disposed on the sixth sub-power supply line.

9. The display device of claim 6, wherein the pixel electrode and the sixth sub-power supply line include a same material.

10. The display device of claim 6, wherein the sixth sub-power supply line includes a material different from a material of the fourth sub-power supply line and from a material of the fifth sub-power supply line.

11. The display device of claim 6, wherein the third sub-power supply line and the sixth sub-power supply line include a same material.

12. The display device of claim 6, wherein
the first sub-power supply line and the fourth sub-power supply line include a same material, and
the second sub-power supply line and the fifth sub-power supply line include a same material.

13. The display device of claim 6, wherein an upper surface of the fifth sub-power supply line is in contact with a lower surface of the sixth sub-power supply line.

14. A display device comprising:
a substrate;
a scan line disposed on the substrate;
a first insulating film disposed on the scan line;
a first sub-clock line disposed on the first insulating film and applied by a clock signal;
a first organic film disposed on the first sub-clock line;
a second sub-clock line disposed on the first organic film and electrically connected to the first sub-clock line through a first contact hole formed in the first organic film;
a third sub-clock line disposed on the second sub-clock line;
a pixel electrode disposed on the first organic film;
a light-emitting element disposed on the pixel electrode;
a planarization film disposed on sides of the light-emitting element; and
a common electrode disposed on the light-emitting element and the planarization film, wherein
the planarization film is disposed on the third sub-clock line.

15. The display device of claim 14, further comprising:
a scan driver that applies a scan signal to the scan line in accordance with the clock signal.

16. The display device of claim 14, wherein the pixel electrode and the third sub-clock line include a same material.

17. The display device of claim 14, wherein the pixel electrode and the third sub-clock line include a material different from a material of the first sub-clock line and from a material of the second sub-clock line.

18. A display device comprising:
a substrate;
an insulating film disposed on the substrate;
a pad disposed on the insulating film;
a first organic film disposed on the pad;
a pad-shielding electrode disposed on the first organic film and electrically connected to the pad through a pad hole formed in the first organic film;
a pixel electrode disposed on the first organic film;
a light-emitting element disposed on the pixel electrode;
a planarization film disposed on sides of the light-emitting element; and
a common electrode disposed on the light-emitting element and the planarization film.

19. The display device of claim 18, further comprising:
a first sub-power supply line disposed on the insulating film and applied by a first power supply voltage;
a second sub-power supply line disposed on the first organic film and electrically connected to the first sub-power supply line through a first power supply hole formed in the first organic film; and
a third sub-power supply line disposed on the second sub-power supply line, wherein
the first sub-power supply line and the pad include a same material.

20. The display device of claim 19, wherein the pad-shielding electrode includes a transparent conductive oxide (TCO).
